(19) United States
(12) Patent Application Publication
(10) Pub. No.: US 2026/0223666 A1
(43) Pub. Date: Jul. 30, 2026

(54) STACKED CAPACITOR DEVICE AND MANUFACTURING METHOD THEREOF

(71) Applicant: Winbond Electronics Corp., Taichung City (TW)

(72) Inventors: Jin-Neng Wu, Kaohsiung City (TW); Shuo-Che Chang, Taichung (TW)

(73) Assignee: Winbond Electronics Corp., Taichung City (TW)

(21) Appl. No.: 19/236,998

(22) Filed: Jun. 13, 2025

(30) Foreign Application Priority Data
Jan. 24, 2025 (TW) 114103637

(51) Int. Cl. H10W 20/40; H10D 80/30; H10W 20/00; H10W 20/20; H10W 90/00; H10W 80/00; H10W 90/20; H10W 90/26

(52) U.S. Cl. CPC H10W 20/496; H10D 80/30; H10W 20/023; H10W 20/056; H10W 20/076; H10W 20/089; H10W 20/20; H10W 90/00; H10W 80/312; H10W 80/327; H10W 90/26; H10W 90/297; H10W 90/792

(57) ABSTRACT

A stacked capacitor device, including at least one first die, at least one second die, and a plurality of through-substrate via structures, is provided. A first capacitor element is disposed on a first surface of the first die, a second capacitor element is disposed on a first surface of the second die, and the first surface of the second die faces towards the first surface of the first die. The through-substrate via structures extending from a second surface of the second die through the second die are respectively coupled to the first capacitor element and the second capacitor element. The number of the first die is one or more. The number of the second die is one or more.

### CROSS-REFERENCE TO RELATED APPLICATION

This application claims the priority benefit of Taiwan application serial no. 114103637, filed on January 24, 2025. The entirety of the above-mentioned patent application is hereby incorporated by reference herein and made a part of this specification.

### BACKGROUND

### Technical Field

The disclosure relates to a semiconductor packaging structure and particularly relates to a stacked capacitor device and a manufacturing method thereof.

### Description of Related Art

As the economic benefits of Moore's Law diminish, it is no longer possible to rely solely on a few directions such as process and architecture to achieve exponential improvements in performance and complexity. Therefore, the industry has shifted from simply relying on process improvements to drive the increase in the number of transistors per unit area on a single silicon wafer, to improving overall performance and functionality through complex system-level chip designs with relatively controllable costs. Among them, Chiplets have received significant attention, as it may achieve higher transistor density and performance at relatively lower costs.

Chiplet is a method of dividing the many components originally included in a single chip into individual small units, each with enhanced functionality, redesigned and remanufactured, to form a system chip through advanced packaging technology. As a result, a single capacitor element (Si Cap) has emerged to meet this need.

However, due to the limited surface area of the chip carrier, any expansion of the capacitance may only be achieved in terms of the vertical direction. Nevertheless, excessively high capacitor elements often face the problem of collapse.

The disclosure provides a stacked capacitor device, which may increase capacitance through a plurality of stacked and bonded dies.

The disclosure also provides a manufacturing method of a stacked capacitor device, which may increase capacitance while avoiding the fabrication of excessively high capacitor elements.

A stacked capacitor device of the disclosure includes at least one first die, a first capacitor element, at least one second die, a second capacitor element, and a plurality of through-substrate via structures. The first capacitor element is disposed on a first surface of the first die, the second capacitor element is disposed on a first surface of the second die, and the first surface of the second die faces towards the first surface of the first die. The plurality of through-substrate via (TSV) structures extending from a second surface of the second die through the second die are respectively coupled to the first capacitor element and the second capacitor element.

The second die includes a dielectric layer, and the second capacitor element is disposed on a surface of the dielectric layer. The second capacitor element includes a trench capacitor, and the trench capacitor is formed within the dielectric layer. The first and second capacitor elements include stacked capacitors.

The stacked capacitor device also includes a redistribution layer disposed on the second surface of the second die, and the redistribution layer is coupled to the through-substrate via structures. The first surface of the second die is bonded to the first surface of the first die. The first surface of the first die includes a BEOL structure formed above the first capacitor element, and the BEOL structure includes an interconnection layer with a multi-layer structure. A part of the through-substrate via structures extends through the second die and is connected to the interconnection layer of the BEOL structure. The number of the first die is plural, and each of the plurality of first dies has the first capacitor element on its first surface. The number of the second die is plural, and each of the plurality of second dies has the second capacitor element on its first surface.

A manufacturing method of a stacked capacitor device of the disclosure includes the following steps. A first die is prepared, where a first capacitor element is formed on a first surface of the first die. A second die is prepared, where a second capacitor element is formed on a first surface of the second die. The second die is stacked on the first die, where the first surface of the second die faces towards the first surface of the first die. A second surface of the second die is thinned, where the second surface is opposite to the first surface of the second die. A plurality of through-substrate via structures are formed, where the through-substrate via structures extending from the second surface of the second die through the second die are respectively coupled to the first capacitor element and the second capacitor element.

The step of preparing the second die includes forming the second capacitor element on a semiconductor substrate. The step of preparing the second die includes first forming a dielectric layer on the semiconductor substrate, then forming the second capacitor element on the dielectric layer. The step of thinning the second surface of the second die includes removing the semiconductor substrate. After forming the through-substrate via structures, it may also include forming a redistribution layer on the second surface of the second die, where the redistribution layer is coupled to the plurality of through-substrate via structures. The method of stacking the second die on the first die includes fusion bonding or hybrid bonding the first die and the second die.

Before the step of forming the through-substrate via structures, it may also include repeating the following steps at least once. Another second die is prepared. Said another second die is stacked on the first die. A second surface of said another second die is thinned. A plurality of through-substrate via structures are formed, where another second capacitor element is formed on a first surface of said another second die.

In another embodiment of the disclosure, after the step of forming the through-substrate via structures, it may also include the following steps. Another first die is prepared. Another second die is prepared. Said another second die is stacked on said another first die. A second surface of said another first die is thinned. A second surface of said another second die is thinned. The second surfaces of the two dies are bonded to each other, where another first capacitor element is formed on a first surface of said another first die, and another second capacitor element is formed on a first surface of said another second die.

A first part of the through-substrate via structures is coupled to a first capacitor electrode of the first capacitor element and a first capacitor electrode of the second capacitor element, and a second part of the through-substrate via structures is coupled to a second capacitor electrode of the first capacitor element and a second capacitor electrode of the second capacitor element.

Based on the foregoing, the method of the disclosure may stack a plurality of dies, and first fabricate capacitor elements on each die, then couple the capacitor elements of each die with a plurality of through-substrate via structures. Therefore, the process of the disclosure is simple, and it may significantly increase the capacitance while avoiding the fabrication of excessively high capacitor elements.

In order to make the above-mentioned features and advantages of the disclosure clearer and easier to understand, the following embodiments are given and described in details with accompanying drawings as follows.

### BRIEF DESCRIPTION OF THE DRAWINGS

FIGS. 1, 3, 8-9, 11, and 12 are cross-sectional views of stacked capacitor devices according to different embodiments of the disclosure.

FIG. 2 is a schematic view of the circuit connection of the capacitors in the stacked capacitor device of FIG. 1.

FIGS. 4A to 4G, 5A to 5E, 6A to 6D, 7A to 7D, 10A to 10E, and 13A to 13E are schematic cross-sectional views of the manufacturing process of stacked capacitor devices according to different embodiments of the disclosure.

### DESCRIPTION OF THE EMBODIMENTS

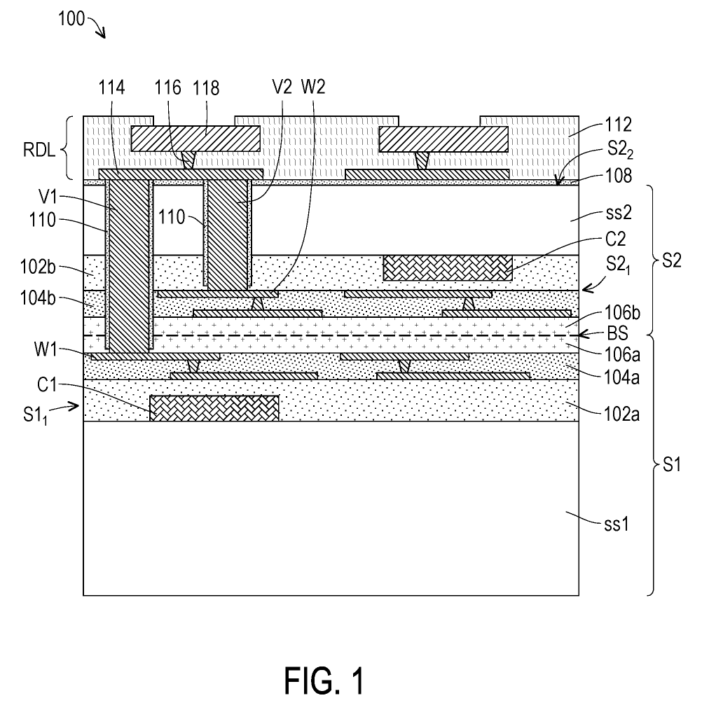

FIG. 1 is a cross-sectional view of a stacked capacitor device according to a first embodiment of the disclosure.

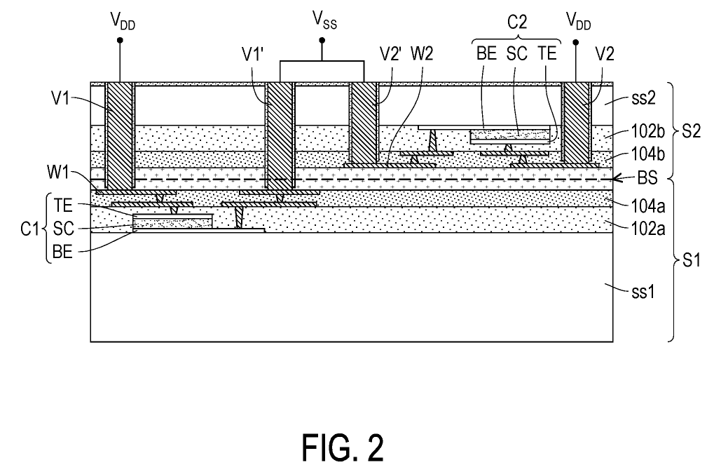

Referring to FIG. 1, a stacked capacitor device 100 of the first embodiment includes a first die S1, a second die S2, a first capacitor element C1, a second capacitor element C2, and a plurality of through-substrate via structures V1 and V2. The first capacitor element C1 is disposed on a first surface S1₁ of the first die S1. For example, the first capacitor element C1 is formed on a semiconductor substrate ss1. The second capacitor element C2 is disposed on a first surface S2₁ of the second die S2. For example, the first capacitor element C1 is formed on another semiconductor substrate ss2. The first surface S2₁ of the second die S2 faces towards the first surface S1₁ of the first die S1. The number of the second die S2 is one, but the disclosure is not limited thereto. The number of the second die S2 may be more than one. The through-substrate via structure V1 and the through-substrate via structure V2 extending from a second surface S2₂ of the second die S2 through the second die S2 are respectively coupled to the first capacitor element C1 and the second capacitor element C2. Details of the circuit connection method will be illustrated in FIG. 2.

Then, the first die S1 may possess an oxide layer 102a formed on the first capacitor element C1 to planarize its surface, so as to facilitate the subsequent formation of lines. The lines are exemplified as formed in the BEOL structure above the semiconductor substrate ss1 and the first capacitor element C1. The BEOL structure includes a BEOL insulation layer 104a and an interconnection layer W1 with a multi-layer structure therein. The BEOL insulation layer 104a is exemplified as an oxide layer, and the interconnection layer W1 includes a copper layer, an aluminum layer, or a combination thereof. The second die S2 may similarly possess an oxide layer 102b formed on the second capacitor element C2 to planarize its surface, so as to facilitate the subsequent formation of lines. The lines are exemplified as formed in the BEOL structure above the semiconductor substrate ss2 and the second capacitor element C2. The BEOL structure includes a BEOL insulation layer 104b and an interconnection layer W2 with a multi-layer structure therein. The BEOL insulation layer 104b is exemplified as an oxide layer, and the interconnection layer W2 includes a copper layer, an aluminum layer, or a combination thereof. The stacked capacitor device 100 is obtained through bonding the first surface S1₁ of the first die S1 and the first surface S2₁ of the second die S2. For example, an oxide layer 106a formed on the BEOL insulation layer 104a and an oxide layer 106b formed on the BEOL insulation layer 104b may be bonded via fusion bonding or hybrid bonding, thereby bonding the second die S2 to the first die S1, and forming a bonding face BS between the oxide layer 106a and the oxide layer 106b.

In FIG. 1, the through-substrate via structure V1 and the through-substrate via structure V2 are connected to the interconnection layer W1 and the interconnection layer W2 respectively, and a hardmask layer 108 may be disposed on the second surface S2₂ of the second die S2, so as to facilitate the formation of the through-substrate via structure V1 and the through-substrate via structure V2. The material of the through-substrate via structure V1 and the through-substrate via structure V2 is exemplified as copper or other suitable metal or alloy, and a liner layer 110 may be disposed on the sidewall of the through-substrate via structure V1 and the sidewall of the through-substrate via structure V2, exemplified as a silicon oxide layer or other suitable insulation material layer. In FIG. 1, the liner layer 110 does not contact the interconnection layer W1 and/or the interconnection layer W2, the liner layer 110 may directly contact the interconnection layer W1 and/or the interconnection layer W2.

The stacked capacitor device 100 of the first embodiment also includes a redistribution layer RDL disposed on the second surface S2₂ of the second die S2, and the redistribution layer RDL is coupled to the through-substrate via structures V1 and V2. The redistribution layer RDL includes a redistribution insulation layer 112 and conductive redistribution patterns extending within the redistribution insulation layer 112. For example, the redistribution insulation layer 112 may include polyimide (PI) or other suitable materials. The redistribution patterns may include a plurality of conductive lines 114 and redistribution vias 116. The redistribution layer RDL may also include pads 118. The conductive lines 114 below are connected with the pads 118 above through the redistribution vias 116.

The first capacitor element C1 is electrically connected to the interconnection layer W1, so the through-substrate via structure V1 may be coupled to the first capacitor element C1 via the interconnection layer W1. Similarly, the second capacitor element C2 is electrically connected to the interconnection layer W2, so the through-substrate via structure V2 may be coupled to the second capacitor element C2 via the interconnection layer W2. The detailed circuit connection is shown in FIG. 2, where in FIG. 2, the same or similar components are denoted by the same reference numerals as those in FIG. 1, and details of the same or similar components may be found in the descriptions of FIG. 1 and will not be repeated here. Moreover, in order to show the circuit connection in the same cross-section, FIG. 2 appears to have a larger area than FIG. 1, but it should be known that the structures in FIG. 2 (such as different through-substrate via structures) may be distributed in different cross-sections, so the overall area of the stacked capacitor device will not increase as a result.

Referring to FIG. 2, the first capacitor element C1 includes a first capacitor electrode TE, a second capacitor electrode BE, and a dielectric layer SC between the first capacitor electrode TE and the second capacitor electrode BE. The second capacitor element C2 similarly includes a first capacitor electrode TE, a second capacitor electrode BE, and a dielectric layer SC between the first capacitor electrode TE and the second capacitor electrode BE. The first capacitor element C1 and the second capacitor element C2 in the diagram are schematic structures, which may be plane capacitors, trench capacitors, cylindrical capacitors, or a combination thereof. The through-substrate via structure V1 is coupled to the first capacitor electrode TE of the first capacitor element C1, the through-substrate via structure V2 is coupled to the first capacitor electrode TE of the second capacitor element C2, a through-substrate via structure V1' is coupled to the second capacitor electrode BE of the first capacitor element C1, and a through-substrate via structure V2' is coupled to the second capacitor electrode BE of the second capacitor element C2. Therefore, a part of the through-substrate via structures V1 and V2 is coupled to the first capacitor electrodes TE of different capacitor elements, while another part of the through-substrate via structures V2' and V1' is coupled to the second capacitor electrodes BE of different capacitor elements. In FIG. 2, both through-substrate via structure V1 and through-substrate via structure V2 are connected to the power voltage (V_{DD}), so the first capacitor electrodes TE of both the first capacitor element C1 and the second capacitor element C2 are coupled to V_{DD}. In contrast, the through-substrate via structures V1 and V2 in FIG. 1 may be electrically connected to the same pad 118 via the conductive lines 114 in the redistribution layer RDL. Similarly, both through-substrate via structure V1' and through-substrate via structure V2' are connected to the ground voltage (V_{SS}), so the second capacitor electrodes BE of both the first capacitor element C1 and the second capacitor element C2 are coupled to V_{SS}, and so on and so forth.

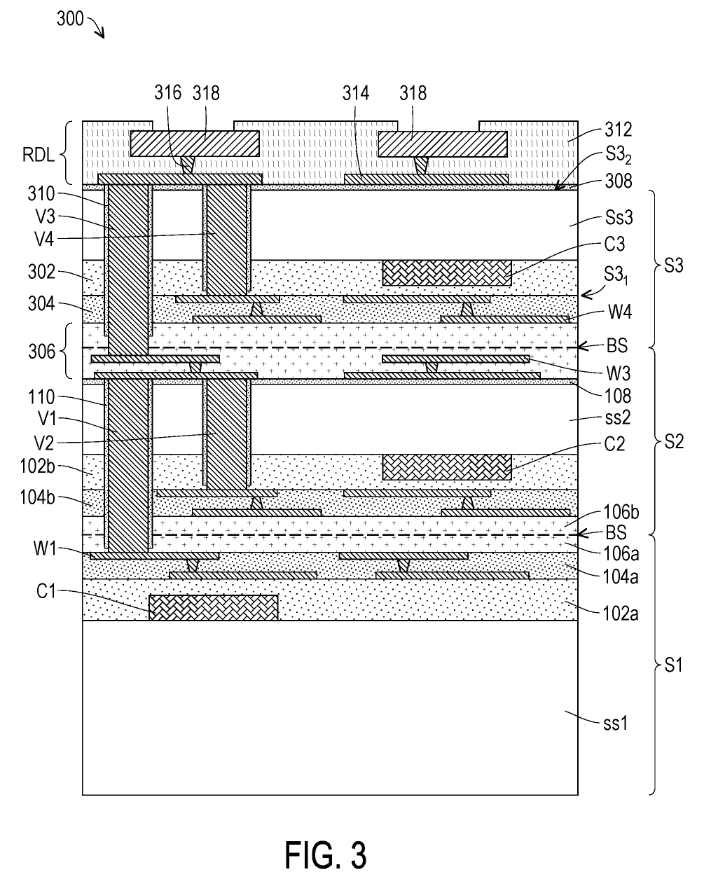

FIG. 3 is a cross-sectional view of a stacked capacitor device according to a second embodiment of the disclosure.

Referring to FIG. 3, the difference between a stacked capacitor device 300 and the first embodiment lies in that a third die S3 is further stacked on top of the second die S2, that is, two dies are stacked on top of the first die S1 (which may also be viewed as two second dies S2). A third capacitor element C3 is disposed on a first surface S3₁ of the third die S3. For example, the third capacitor element C3 is formed on yet another semiconductor substrate ss3. The first surface S3₁ of the third die S3 may also have an oxide layer 302 covering the third capacitor element C3 to planarize its surface, so as to facilitate the subsequent formation of lines. The lines may be formed in a BEOL structure on the semiconductor substrate ss3 and the third capacitor element C3. The BEOL structure includes a BEOL insulation layer 304 and an interconnection layer W4 with a multi-layer structure therein. The interconnection layer W4 is electrically coupled to the third capacitor element C3, similar to the circuit connection method of FIG. 2. The BEOL insulation layer 304 may be an oxide layer, and the interconnection layer W4 includes a copper layer, an aluminum layer, or a combination thereof. An interconnection layer W3 may be connected to a through-substrate via structure V4 in the third die S3 via the redistribution layer RDL. The third die S3 in the stacked capacitor device 300 may be bonded to the second die S2 via fusion bonding or hybrid bonding. For example, the oxide layer on the second surface S2₂ of the second die S2 and the oxide layer on the first surface S3₁ of the third die S3 may be bonded to form an oxide layer 306 with the bonding face BS and the interconnection layer W3 with a multi-layer structure therein. The interconnection layer W3 may be connected to the through-substrate via structure V1 and through-substrate via structure V2 in the second die S2 and a through-substrate via structure V3 in the third die S3.

In FIG. 3, a hardmask layer 308 may be disposed on a second surface S3₂ of the third die S3 to facilitate the formation of the through-substrate via structure V3 and the through-substrate via structure V4. The material of the through-substrate via structure V3 and the through-substrate via structure V4 may be copper or other suitable metal or alloy, and a liner layer 310, such as a silicon oxide layer or other suitable insulation material layer, may be disposed on the sidewalls of the through-substrate via structure V3 and the through-substrate via structure V4. In FIG. 3, the liner layer 310 does not contact the interconnection layer W3 and/or the interconnection layer W4, but the disclosure is not limited thereto; the liner layer 310 may directly contact the interconnection layer W3 and/or the interconnection layer W4. As for the redistribution layer RDL, it is disposed on the second surface S3₂ of the third die S3, and the redistribution layer RDL is coupled to the through-substrate via structures V3 and V4. The redistribution layer RDL may include a redistribution insulation layer 312 and conductive redistribution patterns extending within the redistribution insulation layer 312. For example, the redistribution insulation layer 312 may include PI or other suitable materials. The redistribution patterns may include a plurality of conductive lines 314 and redistribution vias 316. The material of the conductive lines 314 and the redistribution vias 316 in the redistribution patterns may be copper, aluminum, tungsten, silver, gold, or other suitable metal or alloy. The redistribution layer RDL may also include pads 318. The conductive lines 314 below are connected with the pads 318 above through the redistribution vias 316. The material of the pads 318 may be aluminum, copper, or other suitable metal or alloy. Conductive terminals (not shown), such as BGA balls or C4 bumps, may also be disposed on the exposed surface of the pads 318.

According to the content disclosed in the second embodiment, a structure of stacking a plurality of dies and packaging them into a single capacitor element (Si Cap) may be realized, which may expand the capacitance within a limited chip carrier area and may avoid the problem of collapse of the excessively high capacitor elements.

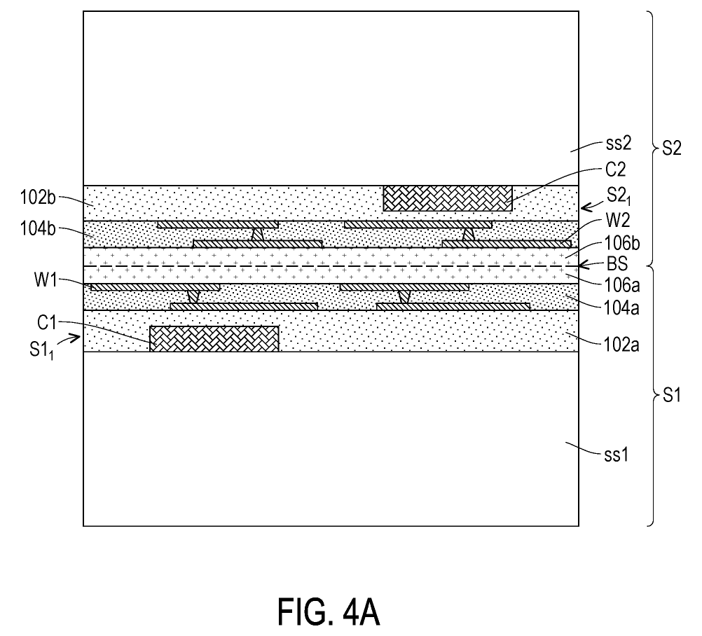

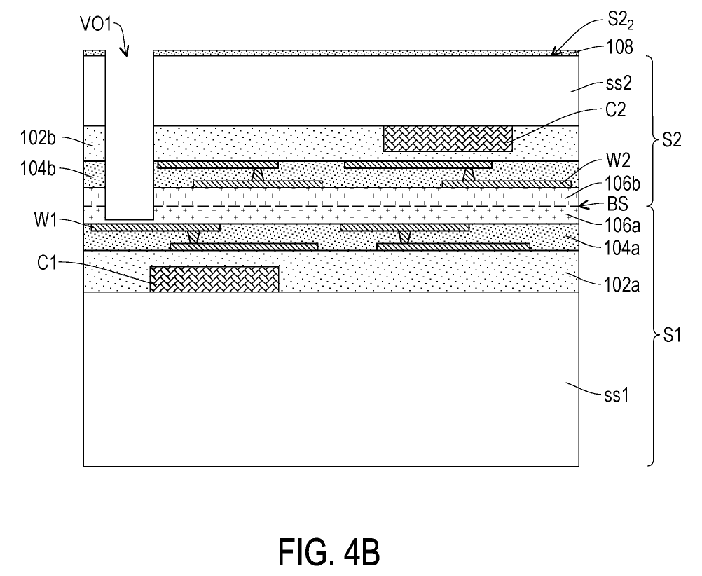

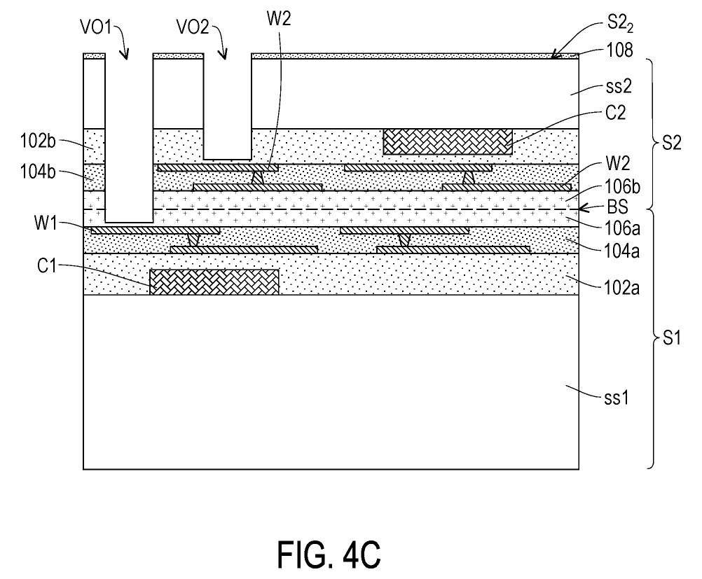

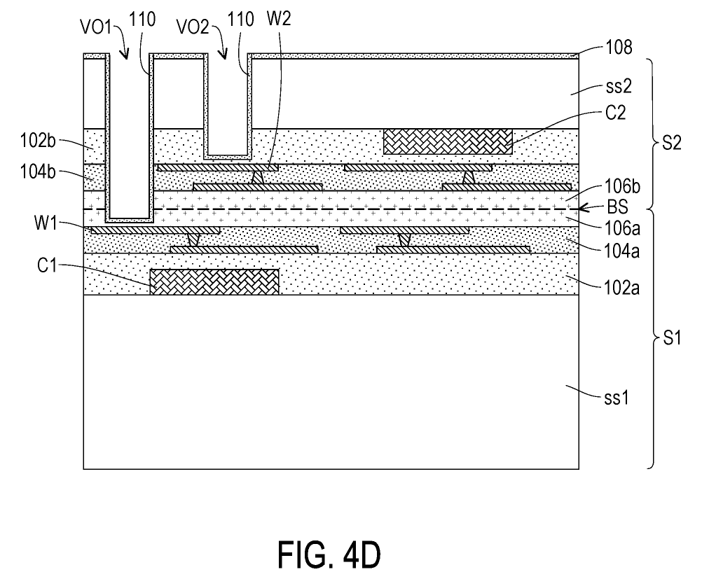

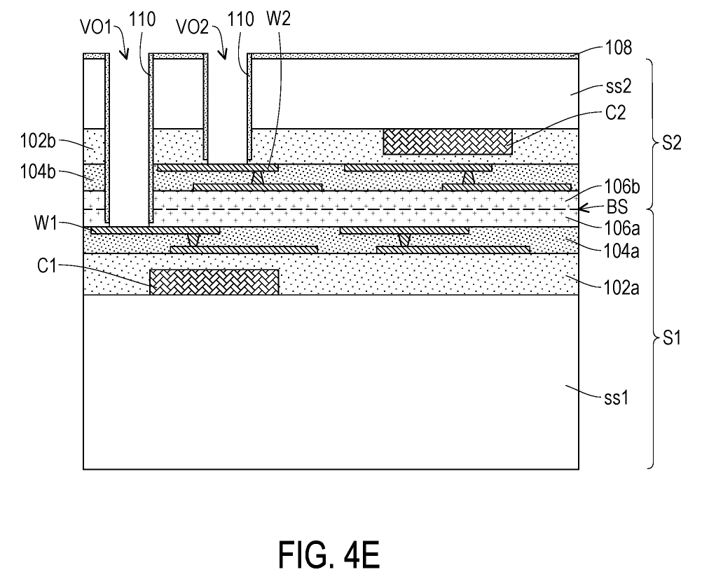

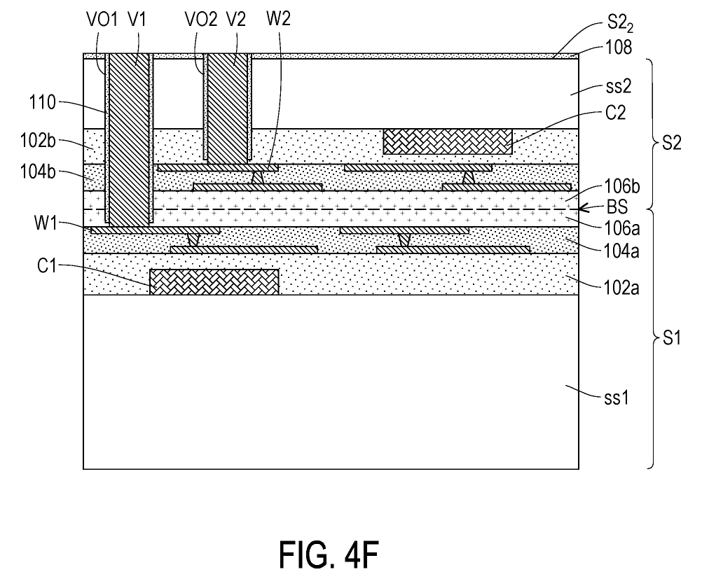

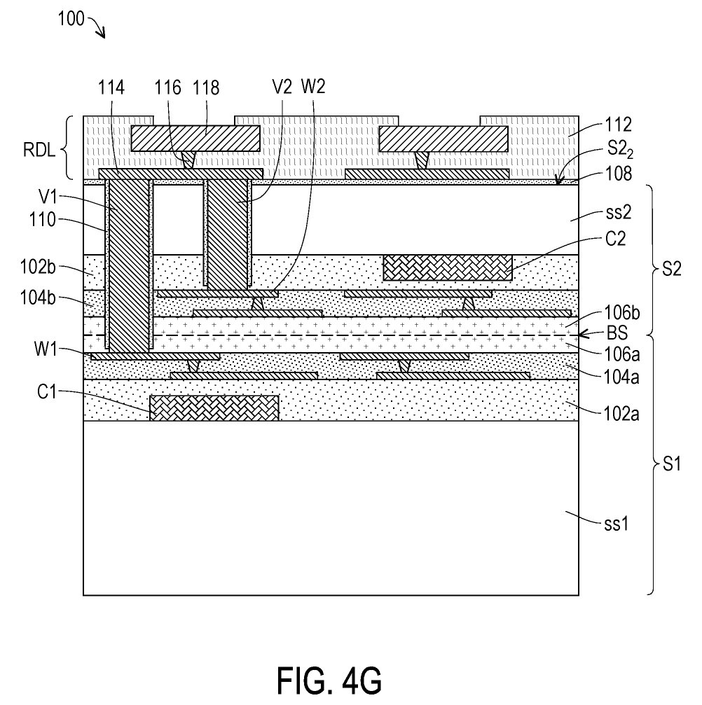

FIG. 4A to FIG. 4G are schematic cross-sectional views of the manufacturing process of a stacked capacitor device according to a third embodiment of the disclosure, where the same or similar components are denoted by the same reference numerals as those in the first embodiment, and details of the same or similar components may be found in the descriptions of the first embodiment and will not be repeated here.

Referring to FIG. 4A, the first die S1 and the second die S2 are first prepared, and the method of preparing the first die S1 may be the same as or different from the method of preparing the second die S2. If the method of preparing the first die S1 is the same as the method of preparing the second die S2, the first die S1 and the second die S2 with the same or similar structures may be formed. On the first surface S1₁ of the first die S1, the first capacitor element C1 is first formed, for example, in the following manner. The first capacitor element C1 is formed on the semiconductor substrate ss1. Then, the oxide layer 102a is formed on the first capacitor element C1 and a planarization process is performed. Subsequently, the BEOL structure including the BEOL insulation layer 104a and the interconnection layer W1 with a multi-layer structure is formed. The interconnection layer W1 is, for example, a copper layer. Then, another oxide layer 106a is formed on the BEOL structure. The second capacitor element C2 is first formed on the first surface S2₁ of the second die S2, for example, in the following manner. The second capacitor element C2 is formed on another semiconductor substrate ss2. Then, the oxide layer 102b is formed on the second capacitor element C2 and a planarization process is performed. Subsequently, the BEOL structure including the BEOL insulation layer 104b and the interconnection layer W2 with a multi-layer structure is formed. The interconnection layer W2 is, for example, a copper layer. Then, another oxide layer 106b is formed on the BEOL structure. Next, the second die S2 is stacked on the first die S1, and the first surface S2₁ of the second die S2 faces towards the first surface S1₁ of the first die S1. The stacking method may include fusion bonding the first die S1 and the second die S2, thereby forming the bonding face BS between the oxide layer 106a and the oxide layer 106b. However, the disclosure is not limited thereto, and the method of stacking the second die S2 on the first die S1 is, for example, a chip-level stacking process with hybrid bonding.

Subsequently, referring to FIG. 4B, after the step of stacking the second die S2 on the first die S1, the step of thinning the second surface S2₂ of the second die S2 is performed. Thinning the second surface S2₂ of the second die S2 may include, for example, thinning the back side of the semiconductor substrate ss2. Afterwards, the hardmask layer 108 may first be formed on the thinned second surface S2₂, then using a photolithography and etching process, an opening VO1 extending from the second surface S2₂ of the second die S2 through the second die S2 is formed, and to prevent oxidation of the interconnection layer W1 (such as the copper layer), the opening VO1 stops within the oxide layer 106a above the interconnection layer W1, without exposing the interconnection layer W1.

Then, referring to FIG. 4C, using another photolithography and etching process, an opening VO2 extending from the second surface S2₂ of the second die S2 through the semiconductor substrate ss2 is formed. The opening VO2 stops within the oxide layer 102b above the interconnection layer W2, without exposing the interconnection layer W2.

Next, referring to FIG. 4D, the liner layer 110, such as a silicon oxide layer or other suitable insulation material layer, is formed on the inner surface of the openings VO1 and VO2. The method of forming the liner layer 110 may include, but is not limited to, first conformally depositing a layer of liner material on the surface of the hardmask layer 108 and the inner surface of the openings VO1 and VO2, and then removing the liner material outside the openings VO1 and VO2.

Subsequently, referring to FIG. 4E, the liner layer 110 at the bottom of the opening VO1 and the opening VO2 is first removed, and then etching is further performed until exposing the interconnection layer W1 beneath the opening VO1 and the interconnection layer W2 beneath the opening VO2. As the thickness of the liner layer 110 inside the openings VO1 and VO2 is similar, and the remaining parts of the oxide layer 106a beneath the opening VO1 and the oxide layer 102b beneath the opening VO2 are approximately the same thickness, this etching step may be performed simultaneously.

Then, referring to FIG. 4F, the through-substrate via structure V1 is formed in the opening VO1, and the through-substrate via structure V2 is formed in the opening VO2. The method of forming the through-substrate via structures V1 and V2 may include, but is not limited to, first depositing metal material to fill the openings VO1 and VO2, and then performing a back-etching or planarization process to remove the metal material outside the openings VO1 and VO2. Moreover, before depositing the metal material, a barrier layer (not shown) may first be formed on the inner surface of the openings VO1 and VO2. The formed through-substrate via structure V1 extends through the second die S2 from the second surface S2₂ and is coupled to the interconnection layer W1, while the formed through-substrate via structure V2 extends through the semiconductor substrate ss2 in the second die S2 from the second surface S2₂ and is coupled to the interconnection layer W2. For the details of the circuit connection method, reference may be made to FIG. 2 and its related description and will not be repeated here.

Referring to FIG. 4G, the redistribution layer RDL may be formed on the second surface S2₂ of the second die S2, and the redistribution layer RDL is coupled to the through-substrate via structures V1 and V2. The method of forming the redistribution layer RDL may include, but is not limited to, first forming the plurality of conductive lines 114 connecting the through-substrate via structures V1 and V2, then depositing the redistribution insulation layer 112, and subsequently forming the redistribution vias 116 and the pads 118 in the redistribution insulation layer 112, and exposing the pads 118. Subsequently, conductive terminals (not shown), such as BGA balls or C4 bumps, may be formed on the exposed surface of the pads 118.

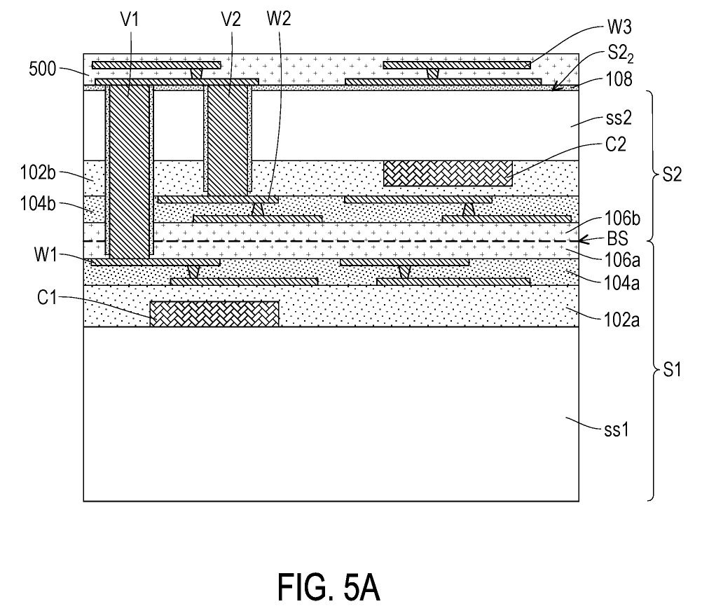

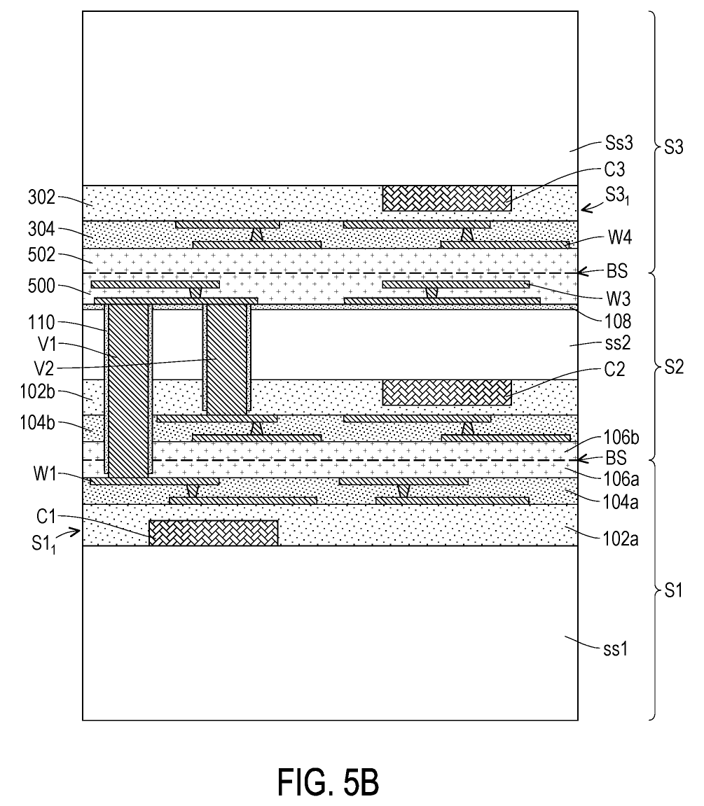

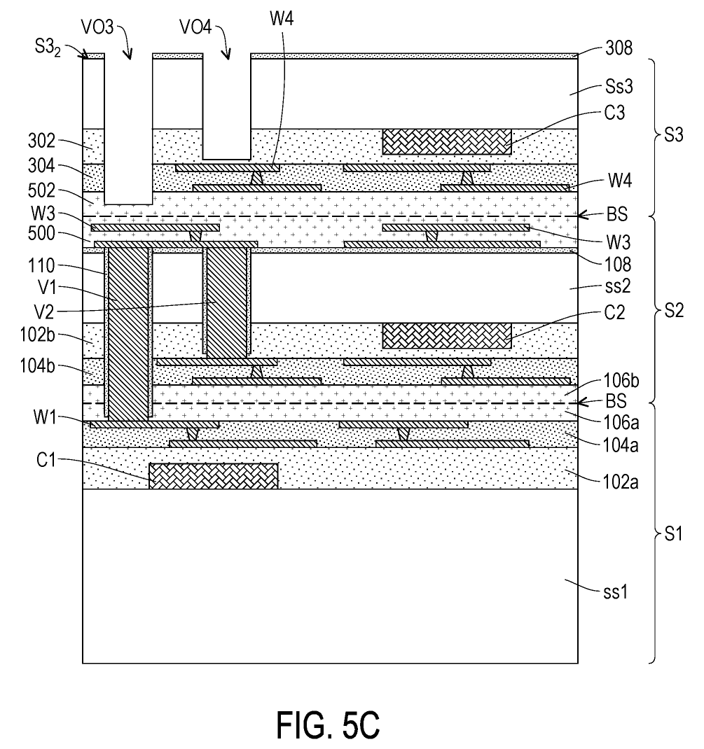

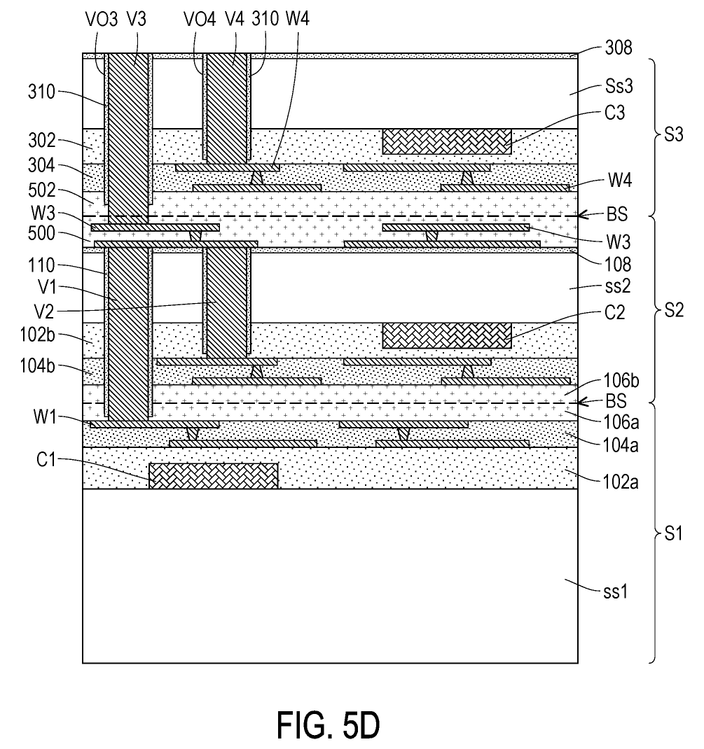

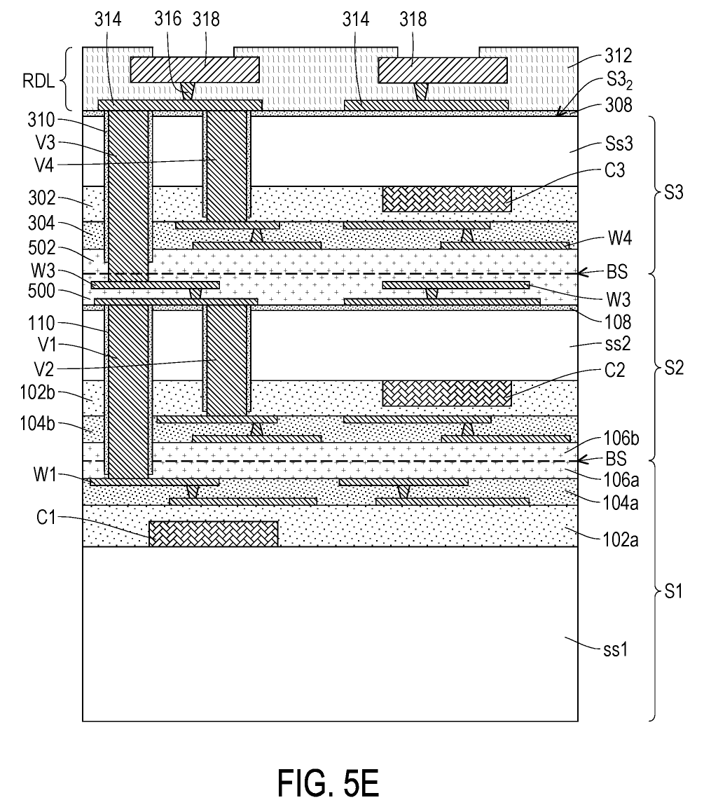

FIG. 5A to FIG. 5E are schematic cross-sectional views of the manufacturing process of a stacked capacitor device according to a fourth embodiment of the disclosure.

Referring to FIG. 5A, for the previous manufacturing process, reference may be made to FIG. 4A to FIG. 4F. On the second surface S2₂ of the second die S2, an oxide layer 500 and the interconnection layer W3 therein are first formed. The interconnection layer W3 is connected to the through-substrate via structures V1 and V2.

Referring to FIG. 5B, the third die S3 is prepared, and the method of preparing the third die S3 may be the same as the method of preparing the second die S2, so the third die S3 may also be viewed as another second die. The third capacitor element C3 is first formed on the first surface S3₁ of the third die S3, for example, in the following manner. The third capacitor element C3 is first formed on the semiconductor substrate ss3. Then, the oxide layer 302 is formed on the third capacitor element C3 and a planarization process is performed. Subsequently, the BEOL structure including the BEOL insulation layer 304 and the interconnection layer W4 with a multi-layer structure is formed. The interconnection layer W4 is, for example, a copper layer, and the interconnection layer W4 is electrically coupled to the third capacitor element C3, similar to the circuit connection method of FIG. 2. Then another oxide layer 502 on the BEOL structure is formed. Next, the third die S3 is stacked on the second die S2. The first surface S3₁ of the third die S3 also faces towards the first surface S1₁ of the first die S1. The method of the stacking may be fusion bonding or hybrid bonding, thereby forming the bonding face BS between the oxide layer 500 and the oxide layer 502.

In FIG. 5C, referring to the method of FIG. 4B and FIG. 4C, after thinning the third die S3, a hardmask layer 308 is formed on the second surface S3₂, and then openings VO3 and VO4 extending from the second surface S3₂ of the third die S3 through the semiconductor substrate ss3 of the third die S3 is formed, where the opening VO3 stops in the oxide layer 502 above the interconnection layer W3, but the disclosure is not limited thereto. The opening VO3 may also stop in the oxide layer 500 above the interconnection layer W3. The formation of the openings VO3 and VO4 may adopt different photolithography and etching processes to form the openings VO3 and VO4 with different depths, and prevent the interconnection layer W3 and interconnection layer W4 (such as copper layer) from being exposed and oxidized.

Subsequently, in FIG. 5D, referring to the method of FIG. 4D to FIG. 4F, the liner layer 310 is formed on the inner surface of openings VO3 and VO4, exposing the interconnection layer W3 beneath the opening VO3 and the interconnection layer W4 beneath the opening VO4, where the through-substrate via structures V3 and V4 are respectively formed therein.

If stacking other dies is required, the steps from FIG. 5A to FIG. 5D may be repeated.

In FIG. 5E, referring to the method of FIG. 4G, the redistribution layer RDL including the redistribution insulation layer 312, the conductive lines 314, the redistribution vias 316, and the pads 318 may be formed on the second surface S3₂ of the third die S3, and the redistribution layer RDL is coupled to the through-substrate via structures V3 and V4.

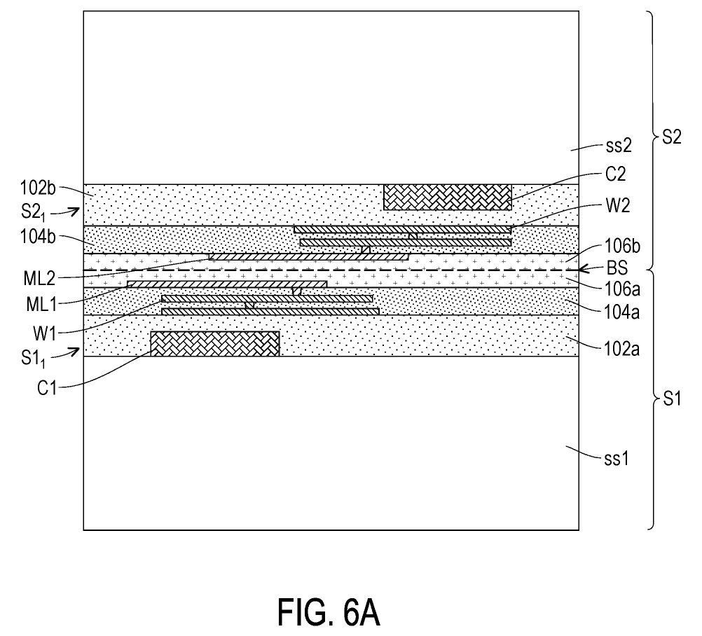

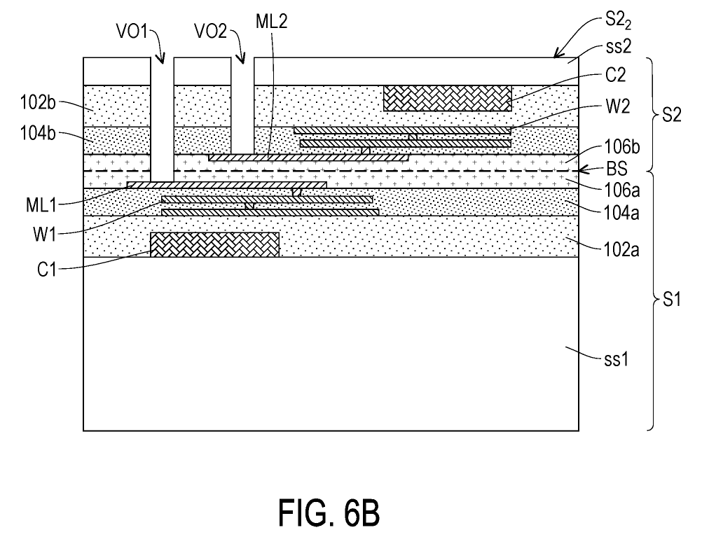

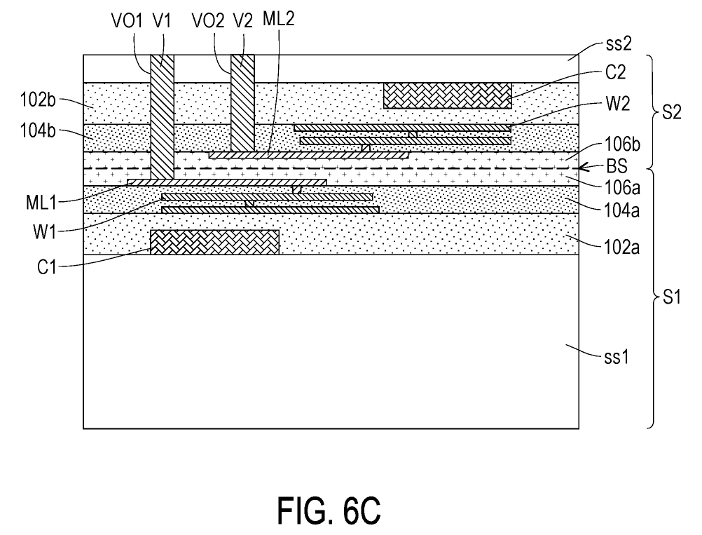

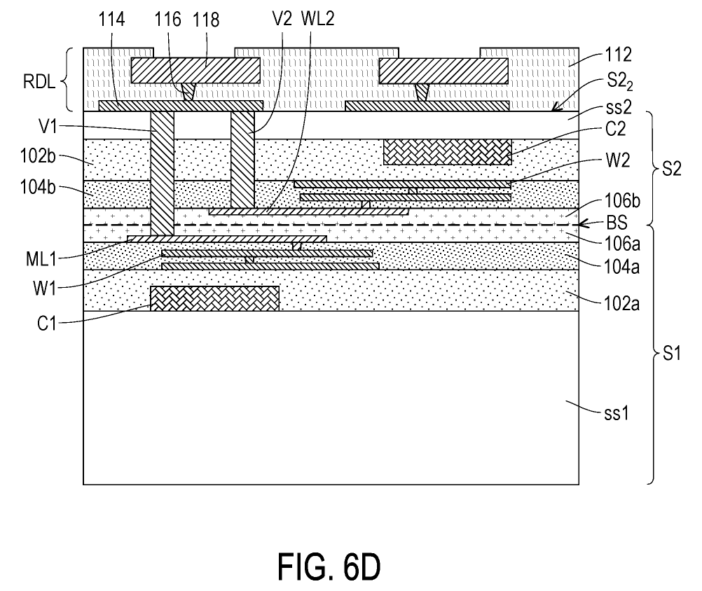

FIG. 6A to FIG. 6D are schematic cross-sectional views of the manufacturing process of a stacked capacitor device according to a fifth embodiment of the disclosure.

Referring to FIG. 6A, the first die S1 and the second die S2 are first prepared, and the method of preparing the first die S1 may be the same as or different from the method of preparing the second die S2. If the method of preparing the first die S1 is the same as the method of preparing the second die S2, the first die S1 and the second die S2 with the same or similar structures may be formed. On the first surface S1₁ of the first die S1, the first capacitor element C1 is first formed, for example, in the following manner. The first capacitor element C1 is first formed on the semiconductor substrate ss1. Then, the oxide layer 102a is formed on the first capacitor element C1 and a planarization process is performed. Subsequently, the BEOL structure, including the BEOL insulation layer 104a and the interconnection layer W1 with a multi-layer structure, is formed thereon. Then, another oxide layer 106a and a metal layer ML1 located in the oxide layer 106a are formed on the BEOL structure, where the metal layer ML1 is electrically connected to the interconnection layer W1, and the metal layer ML1 may be an aluminum layer or other metal material layer that is less prone to oxidation. On the first surface S2₁ of the second die S2, the second capacitor element C2 is first formed, for example, in the following manner. The second capacitor element C2 is first formed on another semiconductor substrate ss2. Then, the oxide layer 102b is formed on the second capacitor element C2 and a planarization process is performed. Subsequently, the BEOL structure, including the BEOL insulation layer 104b and the interconnection layer W2 with a multi-layer structure, is formed thereon. Then, another oxide layer 106b and a metal layer ML2 located in the oxide layer 106b on the BEOL structure are formed, where the metal layer ML2 is electrically connected to the interconnection layer W2, and the metal layer ML2 may be an aluminum layer or other metal material layer that is less prone to oxidation. Next, the second die S2 is stacked on the first die S1. The first surface S2₁ of the second die S2 faces towards the first surface S1₁ of the first die S1. The stacking method may include fusion bonding the first die S1 and the second die S2, thereby forming the bonding face BS between the oxide layer 106a and the oxide layer 106b. However, the disclosure is not limited thereto, and the method of stacking the second die S2 on the first die S1 may be hybrid bonding, for example.

Referring to FIG. 6B, the second surface S2₂ of the second die S2 is thinned, and then using a photolithography and etching process, the openings VO1 and VO2 are simultaneously formed, and the metal layer ML1 in the deeper opening VO1 may be used as an etch stop layer.

Referring to FIG. 6C, the through-substrate via structure V1 is formed in the opening VO1 and the through-substrate via structure V2 is formed in the opening VO2. The method of forming the through-substrate via structures V1 and V2 may include, but is not limited to, first depositing metal material to fill the openings VO1 and VO2, and then performing a back-etching or planarization process to remove the metal material outside the openings VO1 and VO2. Before depositing the metal material, if necessary, a liner layer (not shown), a barrier layer (not shown), or other film layers may be formed on the inner surface or sidewall of the openings VO1 and VO2.

In FIG. 6D, for forming the redistribution layer RDL on the second surface S2₂ of the second die S2, reference may be made to FIG. 4G and its related description and will not be repeated here.

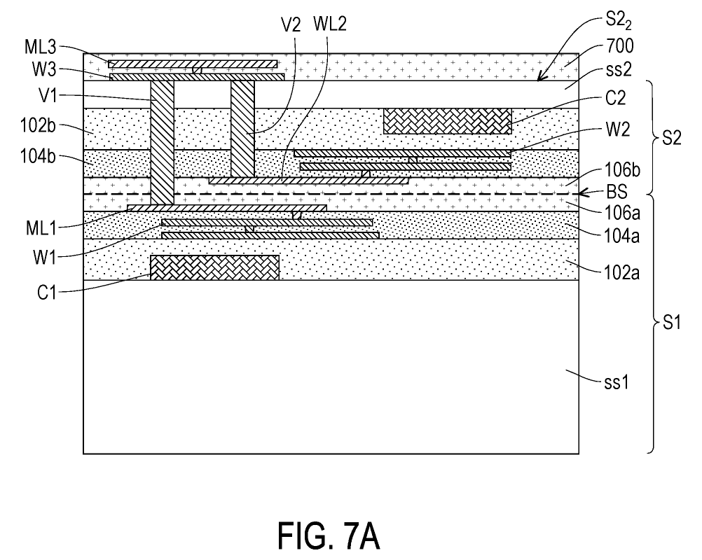

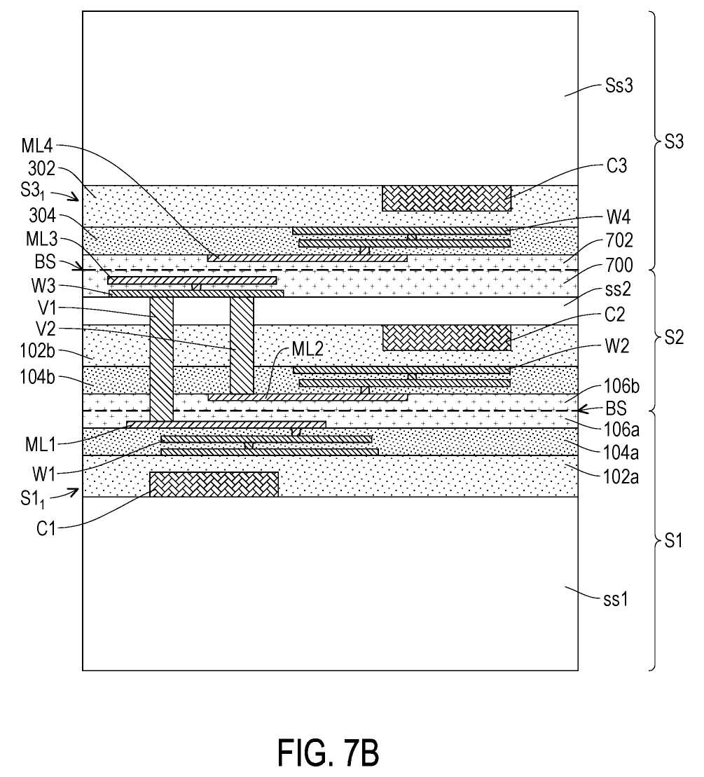

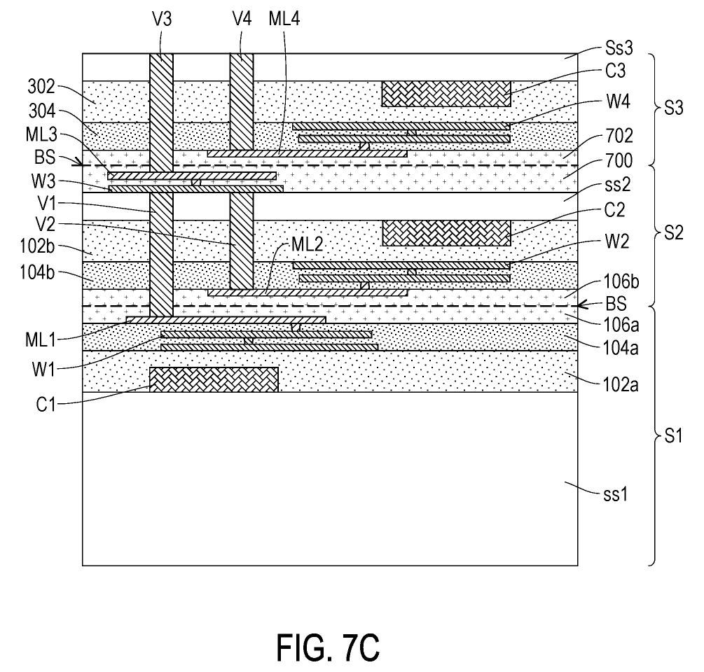

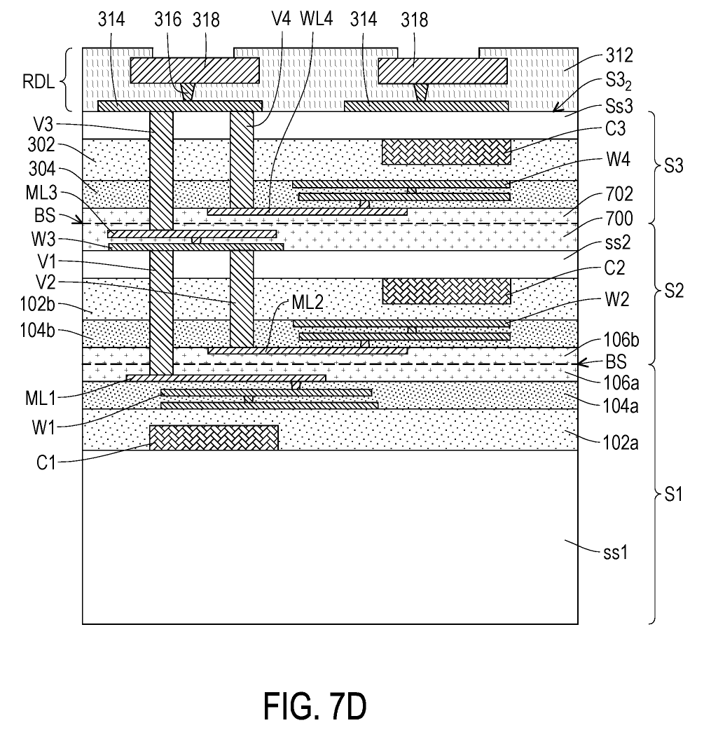

FIG. 7A to FIG. 7D are schematic cross-sectional views of the manufacturing process of a stacked capacitor device according to a sixth embodiment of the disclosure.

Referring to FIG. 7A, for the previous manufacturing process, reference may be made to FIG. 6A to FIG. 6C. On the second surface S2₂ of the second die S2, an oxide layer 700 and the interconnection layer W3 and a metal layer ML3 therein are first formed, where the interconnection layer W3 and the metal layer ML3 are electrically connected. The metal layer ML3 is, for example, an aluminum layer or other metal material layer that is less prone to oxidation.

Referring to FIG. 7B, the third die S3 is prepared, and the method of preparing the third die S3 may be the same as the method of preparing the second die S2, so the third die S3 may also be viewed as another second die. On the first surface S3₁ of the third die S3, the third capacitor element C3 is first formed. The oxide layer 302 may be formed on the third capacitor element C3 and a planarization process may be performed. Then, the BEOL structure, including the BEOL insulation layer 304 and the interconnection layer W4 with a multi-layer structure, is formed thereon. The interconnection layer W4 is electrically coupled to the third capacitor element C3, similar to the circuit connection method of FIG. 2. Then, another oxide layer 702 and a metal layer ML4 therein are formed on the above BEOL structure, and the interconnection layer W4 and the metal layer ML4 are electrically connected, where the metal layer ML4 is, for example, an aluminum layer or other metal material layer that is less prone to oxidation. Next, the third die S3 is stacked on the second die S2. The first surface S3₁ of the third die S3 also faces towards the first surface S1₁ of the first die S1. The method of the stacking may be fusion bonding or hybrid bonding, thereby forming the bonding face BS between the oxide layer 700 and the oxide layer 702.

In FIG. 7C, referring to the method of FIG. 6B to FIG. 6C, the third die S3 is thinned, then the through-substrate via structures V3 and V4 are formed. The through-substrate via structure V3 is coupled to the first capacitor element C1 and the second capacitor element C2 respectively via the metal layer ML3. The through-substrate via structure V4 is coupled to the third capacitor element C3 via the metal layer ML4.

In FIG. 7D, for forming the redistribution layer RDL on the second surface S3₂ of the third die S3, reference may be made to FIG. 5E and its related description and will not be repeated here.

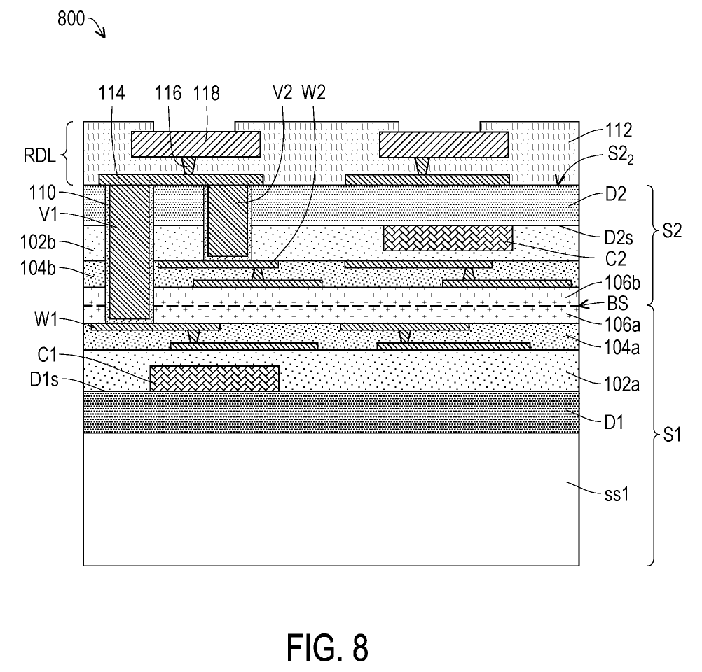

FIG. 8 is a cross-sectional view of a stacked capacitor device according to a seventh embodiment of the disclosure.

Referring to FIG. 8, the difference between a stacked capacitor device 800 and the first embodiment lies in that in the stacked capacitor device 800, except for the first die S1 which possesses the semiconductor substrate ss1, the other dies do not have semiconductor substrates, but instead use a dielectric layer D2, and form the second capacitor element C2 thereon. Therefore, the total thickness of the stacked capacitor device 800 may be significantly reduced. For example, the thickness of the thinned semiconductor substrate may be 10 times or more greater than the thickness of the dielectric layer D2, so the design without a semiconductor substrate is more suitable for application in mobile devices and other devices that originally require a small volume. The dielectric layer D2 and the second capacitor element C2 formed on a surface D2s of the dielectric layer D2, along with the oxide layer 102b and the BEOL structure covering the top of the second capacitor element C2, may be viewed as the second die S2. If the first die S1 and the second die S2 are fabricated using the same process, the first die S1 may include the semiconductor substrate ss1, a dielectric layer D1 thereon, the first capacitor element C1 formed on a surface D1s of the dielectric layer D1, the oxide layer 102a, and the BEOL structure covering the top of the first capacitor element C1. In some embodiments, the material of the dielectric layer D1 and the dielectric layer D2 is, for example, silicon oxide or other suitable dielectric materials.

In FIG. 8, the through-substrate via structure V1 and the through-substrate via structure V2 are connected to the interconnection layer W1 and the interconnection layer W2 respectively. Moreover, since there is no need to etch the semiconductor substrate during the through-via process, the hardmask layer 108 in FIG. 1 may be omitted. Instead, the dielectric layer D2, the oxide layer 102b, the BEOL insulation layer 104b, the oxide layer 106a, and the oxide layer 106b, which have similar etching rates, may be directly etched through, and the etching may stop at the interconnection layer W1 and the interconnection layer W2. Furthermore, since the design without a semiconductor substrate reduces the total thickness of the stacked capacitor device 800, it means that the depth of the through-substrate via structure V1 (and the through-substrate via structure V2) may also decrease accordingly. Therefore, the aspect ratio of the through-substrate via structure V1 and the through-substrate via structure V2 naturally becomes smaller, which may lower the difficulty of the process.

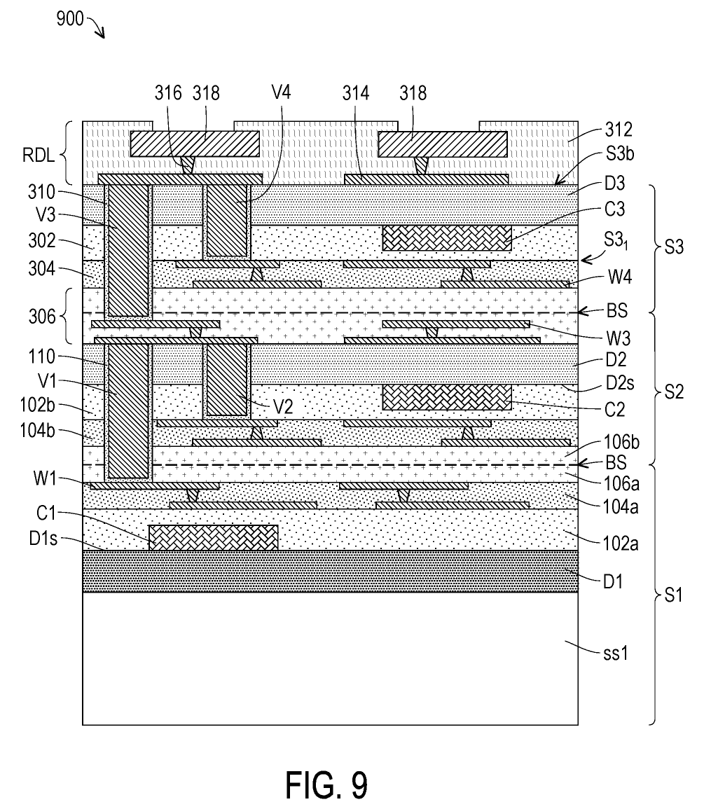

FIG. 9 is a cross-sectional view of another stacked capacitor device of the seventh embodiment.

In FIG. 9, the difference between a stacked capacitor device 900 and the stacked capacitor device 800 of FIG. 8 lies in that the third die S3 is stacked on top of the second die S2, meaning that two dies are stacked on top of the first die S1 (which may also be viewed as two second dies S2). The first surface S3₁ of the third die S3 faces downward. Therefore, the third die S3 similarly does not contain a semiconductor substrate, and may include a dielectric layer D3, the third capacitor element C3 formed on the dielectric layer D3, the oxide layer 302, and the BEOL structure (such as the BEOL insulation layer 304 and the interconnection layer W4) covering the third capacitor element C3. As for the redistribution layer RDL, it is disposed on a back surface D3b of the dielectric layer D3, and the redistribution layer RDL is coupled to the through-substrate via structures V3 and V4. The redistribution layer RDL may include the redistribution insulation layer 312 and the conductive redistribution patterns extending within the redistribution insulation layer 312, such as the conductive lines 314, the redistribution vias 316, and the pads 318, but the disclosure is not limited thereto.

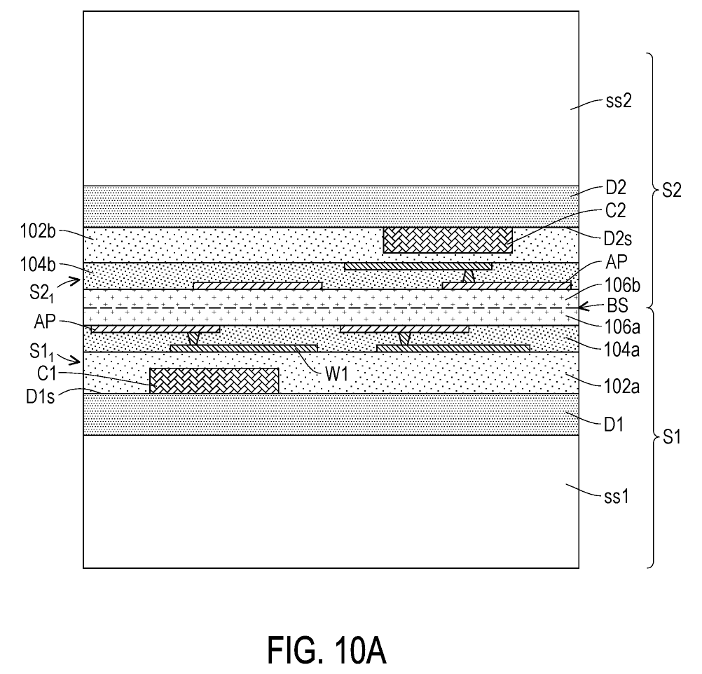

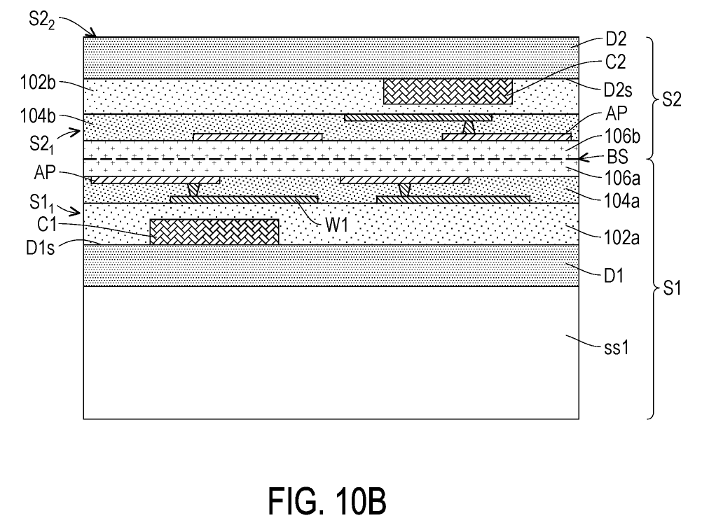

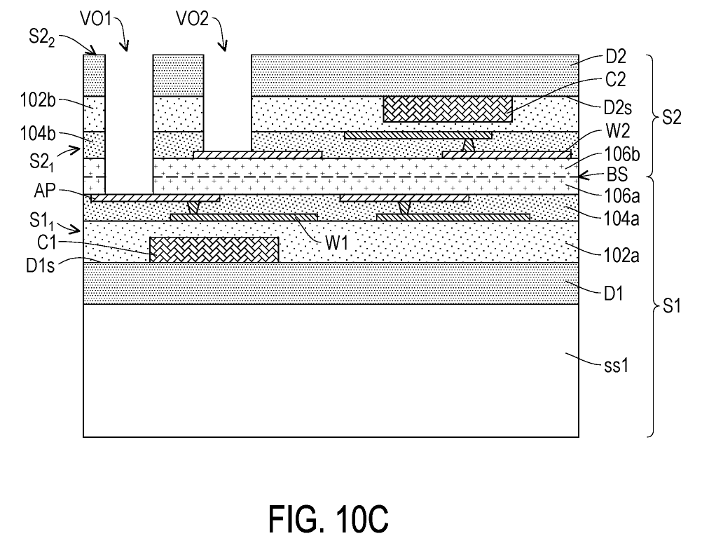

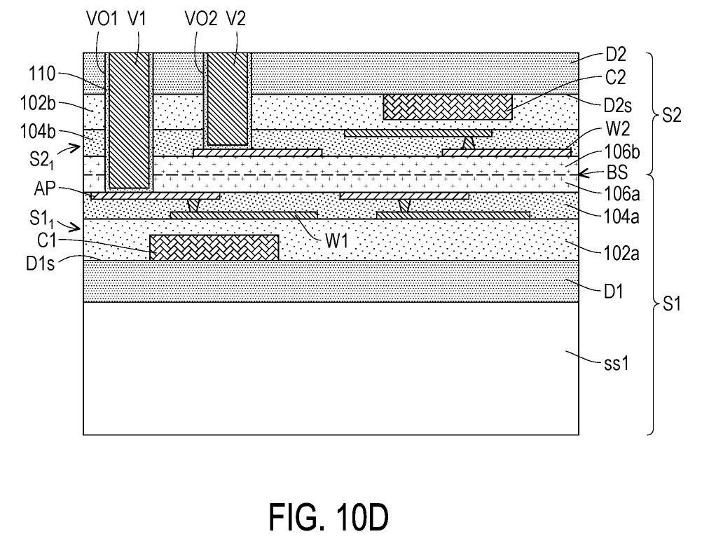

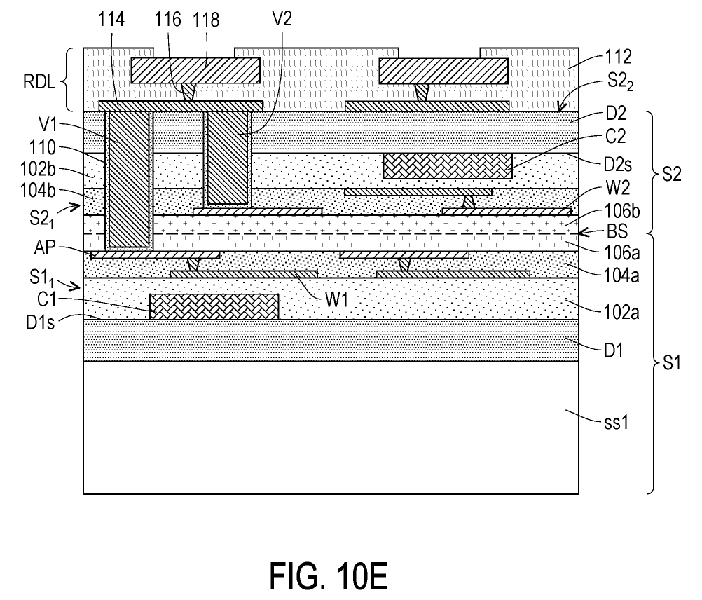

FIG. 10A to FIG. 10E are schematic cross-sectional views of the manufacturing process of a stacked capacitor device according to an eighth embodiment of the disclosure.

Referring to FIG. 10A, the first die S1 and the second die S2 are first prepared, and the method of preparing the first die S1 may be the same as or different from the method of preparing the second die S2. If the method of preparing the first die S1 is the same as the method of preparing the second die S2, the first die S1 and the second die S2 with the same or similar structures may be formed. The method of preparing the first die S1, for example, includes the following: The dielectric layer D1 is formed on the semiconductor substrate ss1. The first capacitor element C1 is formed on the surface D1s of the dielectric layer D1. Then, the oxide layer 102a is formed on the first capacitor element C1. The BEOL structure is formed on the oxide layer 102a, where The BEOL structure may include the BEOL insulation layer 104a, the interconnection layer W1, and an aluminum pad AP that is less easily oxidized. Then, another oxide layer 106a is formed on the BEOL structure. The method of preparing the second die S2 is similar to the method of preparing the first die S1, and includes the following: The dielectric layer D2 is formed on the semiconductor substrate ss2. The second capacitor element C2 is formed on the surface D2s of the dielectric layer D2. Then, the oxide layer 102b is formed on the second capacitor element C2. The BEOL structure is formed on the oxide layer 102b. Another oxide layer 106b is formed on the BEOL structure. Then, the second die S2 is stacked on the first die S1. The first surface S2₁ of the second die S2 faces towards the first surface S1₁ of the first die S1. The stacking method may include fusion bonding or hybrid bonding the first die S1 and the second die S2, thereby forming the bonding face BS between the oxide layer 106a and the oxide layer 106b.

Referring to FIG. 10B, after the step of stacking the second die S2 on the first die S1, the step of thinning the second surface S2₂ of the second die S2 is performed. For example, the semiconductor substrate ss2 shown in FIG. 10A is removed. The semiconductor substrate ss2 may be removed by way of wet etching. The back side of the semiconductor substrate ss2 may first be polished using a planarization process such as CMP, and then the semiconductor substrate ss2 may be completely removed by way of wet etching.

Referring to FIG. 10C, using another photolithography and etching process, openings VO1 and VO2 extending from the second surface S2₂ of the second die S2 through the second die S2 are formed, with the opening VO1 and the opening VO2 stopping at different aluminum pads AP.

Referring to FIG. 10D, the liner layer 110 is formed on the inner surfaces of the openings VO1 and VO2. The method of forming the liner layer 110 includes, but is not limited to, conformally depositing a layer of liner material on the dielectric layer D2 and on the inner surfaces of the openings VO1 and VO2. Then, the through-substrate via structure V1 is formed in the opening VO1 and the through-substrate via structure V2 is formed in the opening VO2. The method of forming the through-substrate via structures V1 and V2 includes, but is not limited to, first depositing metal material to fill the openings VO1 and VO2, and then performing a back-etching or planarization process to remove the metal material and the liner material outside of the openings VO1 and VO2.

Referring to FIG. 10E, the redistribution layer RDL may be formed on the second surface S2₂ of the second die S2, and the redistribution layer RDL is coupled to the through-substrate via structures V1 and V2. The method of forming the redistribution layer RDL includes, but is not limited to, first forming the plurality of conductive lines 114 connecting the through-substrate via structures V1 and V2, then depositing the redistribution insulation layer 112, and subsequently forming the redistribution vias 116 and the pads 118 in the redistribution insulation layer 112, and exposing the pads 118. Subsequently, conductive terminals (not shown), such as BGA balls or C4 bumps, may be formed on the exposed surfaces of the pads 118.

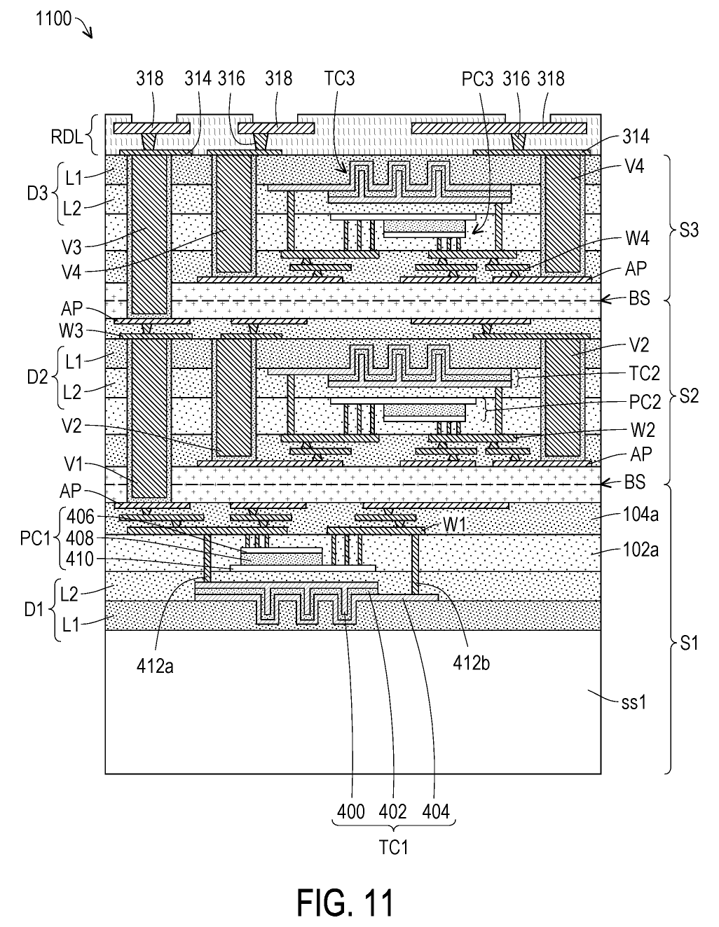

FIG. 11 is a cross-sectional view of a stacked capacitor device according to a ninth embodiment of the disclosure.

Referring to FIG. 11, the difference between a stacked capacitor device 1100 and the stacked capacitor device 900 of FIG. 9 lies in that a trench capacitor TC1 is additionally formed in the dielectric layer D1. The dielectric layer D1 includes a first film layer L1 and a second film layer L2. The first film layer L1 is formed on the semiconductor substrate ss1, the second film layer L2 is formed on the first film layer L1, and the trench capacitor TC1 is formed between the first film layer L1 and the second film layer L2. A planar capacitor PC1 may be formed on the second film layer L2. The trench capacitor TC1 and the planar capacitor PC1 constitute the first capacitor element disposed on the first die S1, thus further increasing the capacitance. The trench capacitor TC1 includes an upper electrode 400, a lower electrode 404, and a dielectric layer 402 between them. The planar capacitor PC1 also includes an upper electrode 406, a lower electrode 410, and a dielectric layer 408 between them. The upper electrode 400 of the trench capacitor TC1 may be electrically connected to the upper electrode 406 of the planar capacitor PC1 through a line structure 412a, and the lower electrode 404 of the trench capacitor TC1 may be electrically connected to the lower electrode 410 of the planar capacitor PC1 through a line structure 412b. The line structure 412a is connected to the interconnection layer W1 in the BEOL structure and may be coupled to the through-substrate via structure V1 via the aluminum pad AP on the interconnection layer W1, which is less prone to oxidation. As for the interconnection layer W1 connected to the line structure 412b, it is also connected to the through-substrate via structure V1 (not shown) formed in other cross-sections.

In FIG. 11, the dielectric layer D2 in the second die S2 similarly has a trench capacitor TC2 and a planar capacitor PC2. The dielectric layer D2 includes a first film layer L1 and a second film layer L2. Since the second die S2 is bonded to the first die S1 after being flipped, the second film layer L2 is located below the first film layer L1. The trench capacitor TC2 is formed between the first film layer L1 and the second film layer L2, and the planar capacitor PC2 is formed on the second film layer L2. Therefore, the trench capacitor TC2 and the planar capacitor PC2 constitute the second capacitor element disposed on the second die S2. The trench capacitor TC2 is similar to the trench capacitor TC1, and the planar capacitor PC2 is similar to the planar capacitor PC1, so for their circuit design and connection method, reference may be made to the first die S1, and different electrodes of the trench capacitor TC2 and the planar capacitor PC2 may be coupled out through different through-substrate via structures V2. The third die S3 is also stacked on top of the second die S2, meaning two dies are stacked on top of the first die S1 (which may also be viewed as two second dies S2). Therefore, the structure of the third die S3 is the same as the structure of the second die S2 and will not be repeated here.

Referring to FIG. 11, the interconnection layer W3 may connect the through-substrate via structure V1 in the second die S2 with the through-substrate via structure V3 in the third die S3, and connect the conductive line 314 below with the pad 318 above through the redistribution via 316 in the redistribution layer RDL. The interconnection layer W4 may couple different electrodes of the trench capacitor TC3 and the planar capacitor PC3 to different through-substrate via structures V4 respectively, and connect to different pads 318 above through the conductive line 314 and the redistribution via 316 in the redistribution layer RDL.

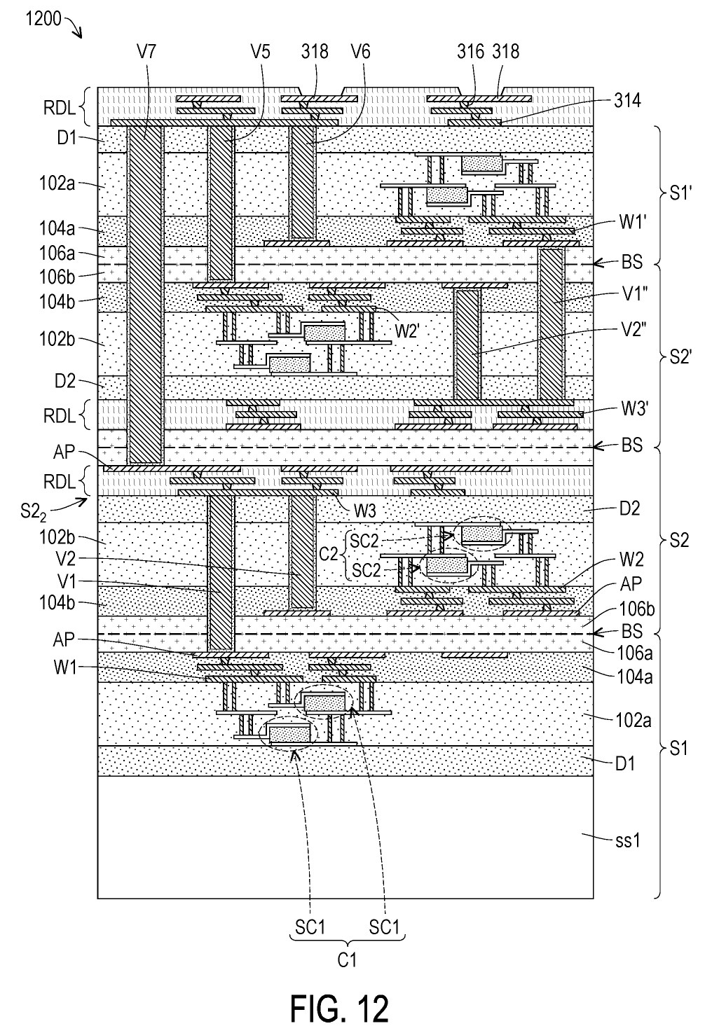

FIG. 12 is a cross-sectional view of a stacked capacitor device according to a tenth embodiment of the disclosure.

Referring to FIG. 12, the difference between a stacked capacitor device 1200 and the ninth embodiment lies in that in the stacked capacitor device 1200, the capacitor elements in the first die S1 and the second die S2 include a plurality of capacitors respectively, such as the first capacitor element C1 including two stacked capacitors SC1, and the second capacitor element C2 including two stacked capacitors SC2, the two stacked capacitors SC1 may be connected in series or in parallel with each other, and the two stacked capacitors SC2 may be connected in series or in parallel with each other. Moreover, the stacking way of dies in the stacked capacitor device 1200 is to stack the second die S2 on the first die S1 and stack the second die S2' on the first die S1' respectively first, and then stack the second die S2' on the second die S2. The first die S1' basically possesses the same components as the first die S1, and the second die S2' basically possesses the same components as the second die S2. The difference between them may only exist in the interconnections of the back-end process and the lines of the redistribution layer. The redistribution layer RDL may be disposed on the second surface S2₂ of the second die S2 to facilitate line connection. Furthermore, the stacked capacitor device 1200 also includes a through-substrate via structure V7 extending through the first die S1' and the second die S2'. In FIG. 12, a through-substrate via structure V1" couples an interconnection layer W1' with an interconnection layer W3', and a through-substrate via structure V2" couples an interconnection layer W2' with the interconnection layer W3. A through-substrate via structure V6 couples the conductive line 314 with the interconnection layer W1', and a through-substrate via structure V5 couples the conductive line 314 with the interconnection layer W2'. Even though some line connections are not illustrated, it should be known that there are interconnect layers connecting them in other cross-sections.

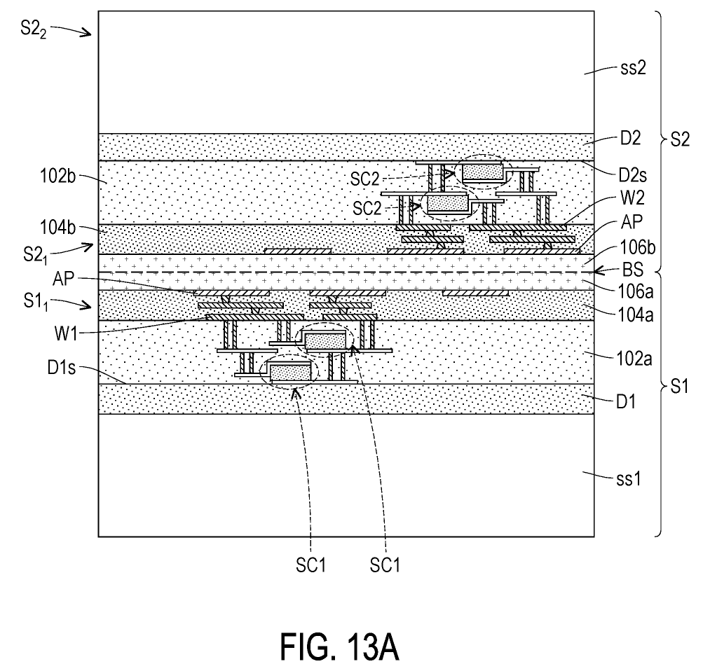

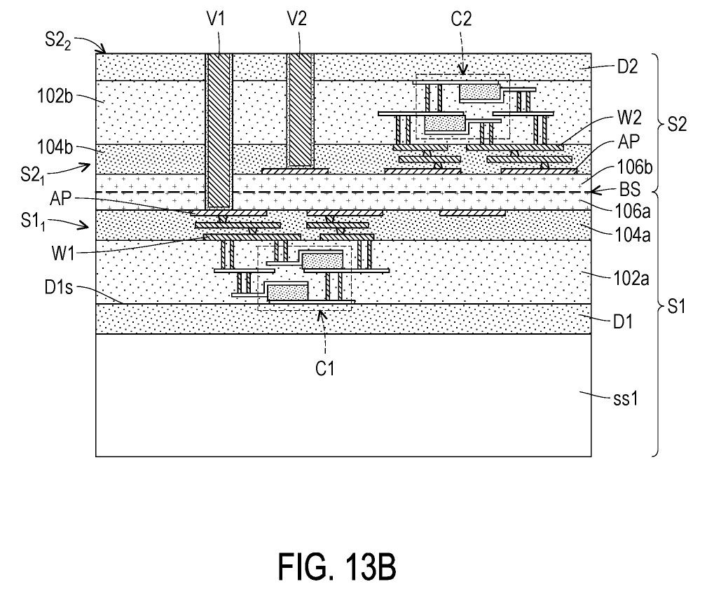

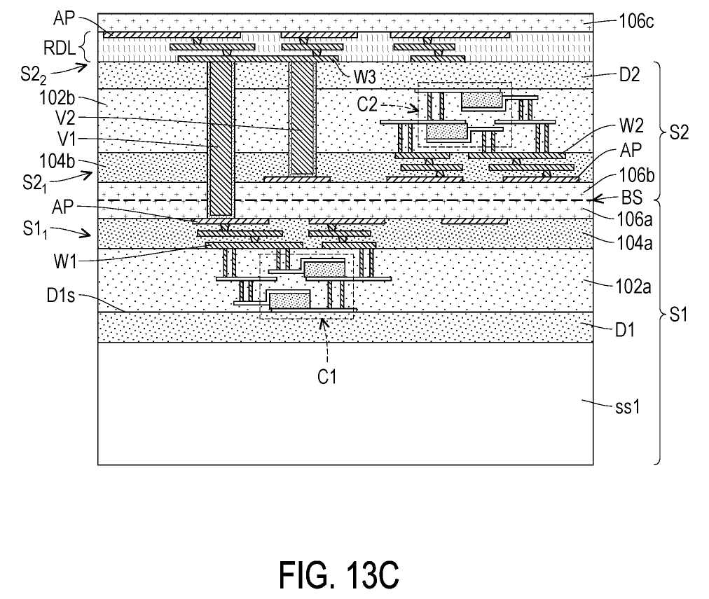

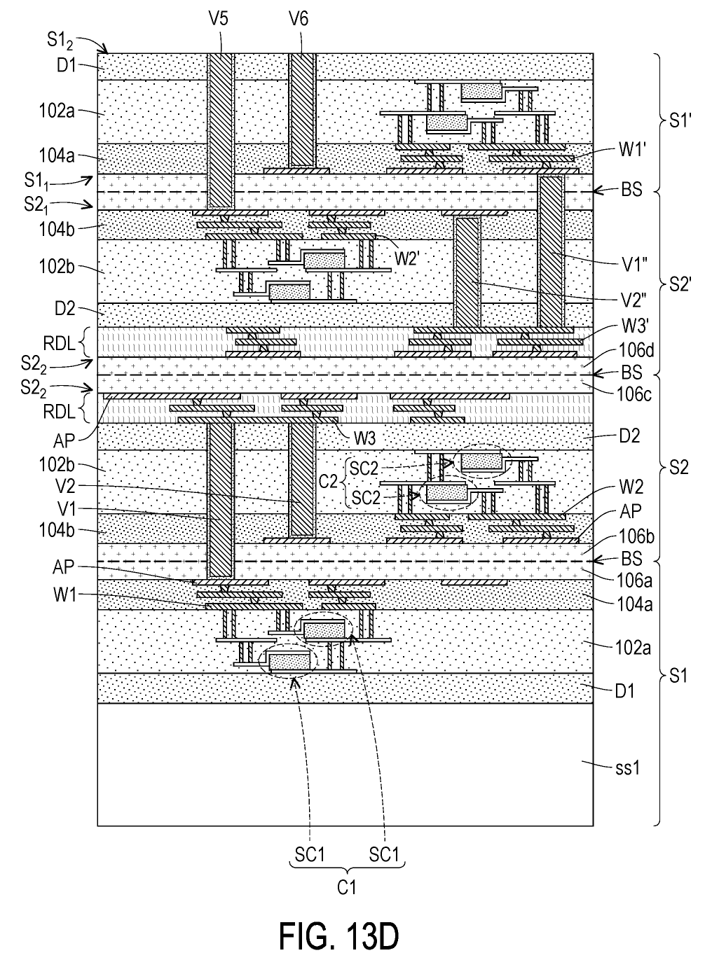

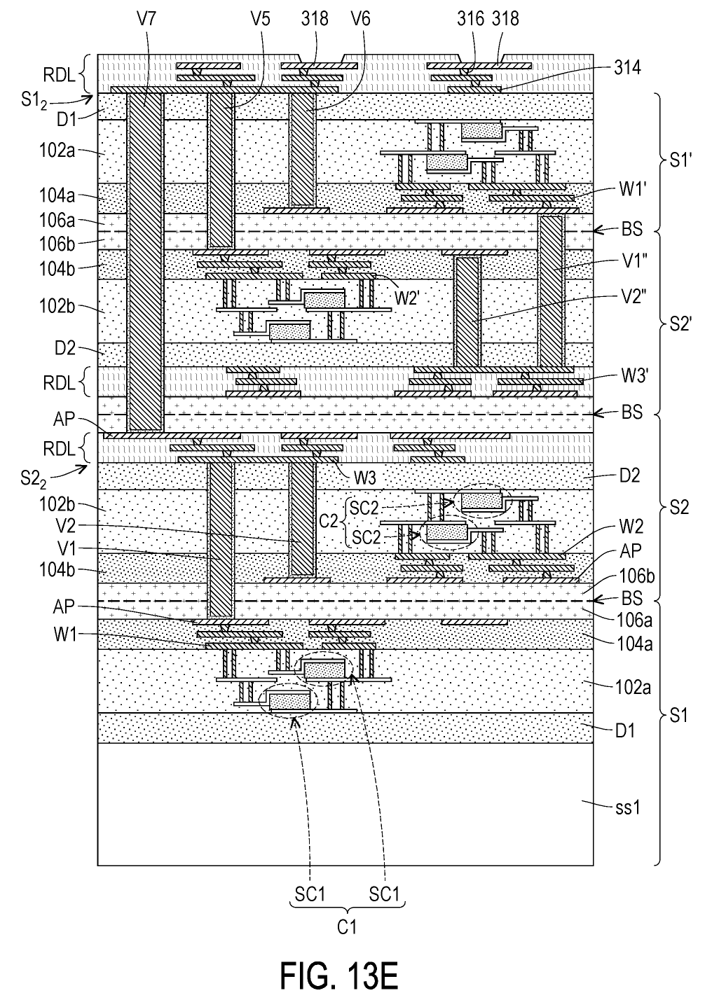

FIG. 13A to FIG. 13E are schematic cross-sectional views of the manufacturing process of a stacked capacitor device according to an eleventh embodiment of the disclosure.

Referring to FIG. 13A, the first die S1 and the second die S2 are first prepared, and for the method for preparing the first die S1 and the second die S2, reference may be made to the content of the embodiments. A plurality of stacked capacitors SC1 may be formed in the first die S1, and a plurality of stacked capacitors SC2 may be formed in the second die S2. Then, the second die S2 is stacked on the first die S1. The first surface S2₁ of the second die S2 faces towards the first surface S1₁ of the first die S1. The stacking method may be fusion bonding or hybrid bonding the first die S1 and the second die S2, thereby forming the bonding face BS between the oxide layer 106a and the oxide layer 106b.

Next, referring to FIG. 13B, after the step of stacking the second die S2 on the first die S1, the step of thinning the second surface S2₂ of the second die S2 is performed. For example, the semiconductor substrate ss2 of FIG. 13A is removed. For the related process, reference may be made to the content of the embodiments. Then, the through-substrate via structures V1 and V2 extending from the second surface S2₂ of the second die S2 through the second die S2 are formed. The through-substrate via structure V1 is located on the aluminum pad AP in the BEOL insulation layer 104a, and the through-substrate via structure V2 is located on the aluminum pad AP in the BEOL insulation layer 104b. The through-substrate via structure V1 is electrically coupled to the first capacitor element C1, and the through-substrate via structure V2 is electrically coupled to the second capacitor element C2. The number of the through-substrate via structures V1 and V2 may be plural, which is similar to the circuit connection method of FIG. 2.

Then, referring to FIG. 13C, the redistribution layer RDL may be formed on the second surface S2₂ of the second die S2, and the redistribution layer RDL is coupled to the through-substrate via structures V1 and V2. For the method of forming the redistribution layer RDL, reference may be made to the content of the embodiments. Next, an oxide layer 106c may be formed on the redistribution layer RDL.

Referring to FIG. 13D, the previous steps are repeated to additionally stack another first die S1' and another second die S2', and after forming another oxide layer 106d on the second surface S2₂ of the second die S2', it may be fusion bonded to the oxide layer 106c. Then, the through-substrate via structures V5 and V6 extending from the second surface S1₂ of the first die S1' through the first die S1' are formed.

Referring to FIG. 13E, a through-substrate via structure V7 extending from the second surface S1₂ of the first die S1' through the first die S1' and the second die S2 is formed, which is located on the aluminum pad AP in the second die S2. Another redistribution layer RDL may be formed on the second surface S1₂, and the redistribution layer RDL is coupled to the through-substrate via structures V5, V6, and V7. For the method of forming the redistribution layer RDL, reference may be made to the content of the embodiments, thereby exposing the pad 318. Subsequently, conductive terminals (not shown), such as BGA balls or C4 bumps, may be formed on the exposed surface of the pad 318.

Although the disclosure has been described with reference to the embodiments above, the embodiments are not intended to limit the disclosure. Any person skilled in the art can make some changes and modifications without departing from the spirit and scope of the disclosure. Therefore, the scope of the disclosure will be defined in the appended claims.

What is claimed is:

1. A stacked capacitor device, comprising:
at least one first die;
a first capacitor element, disposed on a first surface of the at least one first die;
at least one second die, stacked on the first surface of the first die;
a second capacitor element, disposed on a first surface of the at least one second die, wherein the first surface of the at least one second die faces towards the first surface of the at least one first die; and
a plurality of through-substrate via structures, extending from a second surface of the at least one second die through the at least one second die, and respectively coupled to the first capacitor element and the second capacitor element.

2. The stacked capacitor device according to claim 1, wherein the at least one second die comprises a dielectric layer, and the second capacitor element is disposed on a surface of the dielectric layer.

3. The stacked capacitor device according to claim 2, wherein the second capacitor element comprises a trench capacitor, and the trench capacitor is formed within the dielectric layer.

4. The stacked capacitor device according to claim 1, wherein the first capacitor element and the second capacitor element each comprise a plurality of stacked capacitors.

5. The stacked capacitor device according to claim 1, further comprising a redistribution layer, disposed on the second surface of the at least one second die, and coupled to the plurality of through-substrate via structures.

6. The stacked capacitor device according to claim 1, wherein a first part of the plurality of through-substrate via structures is coupled to a first capacitor electrode of the first capacitor element and a first capacitor electrode of the second capacitor element, and a second part of the plurality of through-substrate via structures is coupled to a second capacitor electrode of the first capacitor element and a second capacitor electrode of the second capacitor element.

7. The stacked capacitor device according to claim 1, wherein the first surface of the at least one second die is bonded to the first surface of the first die.

8. The stacked capacitor device according to claim 1, wherein the first surface of the first die comprises a BEOL structure formed above the first capacitor element, and the BEOL structure comprises an interconnection layer with a multi-layer structure.

9. The stacked capacitor device according to claim 8, wherein a part of the plurality of through-substrate via structures extends through the second die and is connected to the interconnection layer of the BEOL structure.

10. The stacked capacitor device according to claim 1, wherein a number of the at least one first die is plural, and the first capacitor element is on the first surface of each of the plurality of first dies.

11. The stacked capacitor device according to claim 1, wherein a number of the at least one second die is plural, and the second capacitor element is on the first surface of each of the plurality of second dies.

12. A manufacturing method of a stacked capacitor device, comprising:
a step of preparing a first die, wherein a first capacitor element is formed on a first surface of the first die;
a step of preparing a second die, wherein a second capacitor element is formed on a first surface of the second die;
a step of stacking the second die on the first die, with the first surface of the second die faces towards the first surface of the first die;
a step of thinning a second surface of the second die, wherein the second surface is opposite to the first surface of the second die; and
a step of forming a plurality of through-substrate via structures, wherein the plurality of through-substrate via structures extending from the second surface of the second die through the second die are respectively coupled to the first capacitor element and the second capacitor element.

13. The manufacturing method of the stacked capacitor device according to claim 12, wherein the step of preparing the second die comprises forming the second capacitor element on a semiconductor substrate.

14. The manufacturing method of the stacked capacitor device according to claim 12, wherein the step of preparing the second die comprises:
forming a dielectric layer on a semiconductor substrate; and
forming the second capacitor element on the dielectric layer.

15. The manufacturing method of the stacked capacitor device according to claim 14, wherein the step of thinning the second surface of the second die comprises removing the semiconductor substrate.

16. The manufacturing method of the stacked capacitor device according to claim 12, wherein after forming the plurality of through-substrate via structures, the method further comprises forming a redistribution layer on the second surface of the second die, and the redistribution layer is coupled to the plurality of through-substrate via structures.

17. The manufacturing method of the stacked capacitor device according to claim 12, wherein a first part of the plurality of through-substrate via structures is coupled to a first capacitor electrode of the first capacitor element and a first capacitor electrode of the second capacitor element, and a second part of the plurality of through-substrate via structures is coupled to a second capacitor electrode of the first capacitor element and a second capacitor electrode of the second capacitor element.

18. The manufacturing method of the stacked capacitor device according to claim 12, wherein the method of stacking the second die on the first die comprises fusion bonding or hybrid bonding the first die and the second die.

19. The manufacturing method of the stacked capacitor device according to claim 12, wherein before the step of forming the plurality of through-substrate via structures, the method further comprises repeating the following steps at least once:
a step of preparing another second die, wherein another second capacitor element is formed on a first surface of the another second die;
a step of stacking the another second die on the first die;
a step of thinning a second surface of the another second die; and
a step of forming a plurality of through-substrate via structures in the another second die.

20. The manufacturing method of the stacked capacitor device according to claim 12, wherein after the step of forming the plurality of through-substrate via structures, the method further comprises:
a step of preparing another first die, wherein another first capacitor element is formed on a first surface of the another first die;
a step of preparing another second die, wherein another second capacitor element is formed on a first surface of the another second die;
a step of stacking the another second die on the another first die;
a step of thinning a second surface of the another second die;
a step of thinning a second surface of the another first die; and
a step of bonding the second surface of the another second die to the second surface of the second die.
